(19) United States
(12) Patent Application Publication
(10) Pub. No.: US 2026/0026236 A1
(43) Pub. Date: Jan. 22, 2026

(54) Display Device

(71) Applicant: LG Display Co., Ltd., Seoul (KR)

(72) Inventors: Eunhyung Lee, Paju-si (KR); Mi-Na Kim, Paju-si (KR); Hyunsook Jeon, Paju-si (KR); Sohee Lee, Paju-si (KR); Moonsung Kil, Paju-si (KR); Yuri Park, Paju-si (KR)

(21) Appl. No.: 19/249,800

(22) Filed: Jun. 25, 2025

(30) Foreign Application Priority Data
Jul. 19, 2024 (KR) 10-2024-0095446

(51) Int. Cl. H10K 59/80; H10K 59/35; H10K 59/40; H10K 59/65; H10K 101/30; H10K 102/00

(52) U.S. Cl. CPC H10K 59/80524; H10K 59/353; H10K 59/40; H10K 59/65; H10K 59/873; H10K 2101/30; H10K 2102/351

(57) ABSTRACT

Disclosed is a display device that is capable of reducing the sheet resistance of an optical area cathode electrode by including a conductive material layer disposed on a common electrode in an optical area where an electronic device is disposed and a transparent electrode disposed on the conductive material layer.

### CROSS-REFERENCE TO RELATED APPLICATION

This application claims priority and the benefit from Republic of Korea Patent Application No. 10-2024-0095446, filed on Jul. 19, 2024, which is hereby incorporated by reference in its entirety.

### BACKGROUND

### Technical Field

Embodiments of the disclosure relate to a display device, and more specifically, for example, without limitation, to a display device capable of reducing the sheet resistance of the cathode electrode disposed in the optical area where an electronic device is disposed.

### Description of Related Art

As the information society develops, demand for display devices for displaying images is increasing in various forms. Various display devices, such as liquid crystal display devices and organic light emitting display devices, are being utilized in recent years.

Further, the display device may provide a detection function to perform a function depending on the light of the ambient environment. To that end, the display device may have various electronic devices (optical electronic devices), such as detection sensors and image sensors (cameras).

Since the electronic device may receive light from the front of the display device, a transmissive area having a hole may be formed in the cathode electrode in the area where the electronic device is disposed.

### SUMMARY

The inventor has realized that in the related art, a deviation may occur in the sheet resistance of the cathode electrode between the area where the electronic device is disposed and the area where it is not, which may result in a pixel deviation between the respective areas. Accordingly, exemplary embodiments of the disclosure may provide a display device capable of reducing the sheet resistance of the cathode electrode disposed in the optical area where an electronic device is disposed.

Exemplary embodiments of the disclosure may provide a display device capable of reducing a luminance deviation between the optical area where an electronic device is disposed and an area other than the optical area.

Exemplary embodiments of the disclosure may provide a display device capable of enhancing the transmittance of the light emitted from a light emitting element.

Exemplary embodiments of the disclosure may provide a display device capable of enhancing the sheet resistance of an optical area cathode electrode by forming a transmissive area without disposing a cathode hole.

Exemplary embodiments of the disclosure may provide a display device capable of enhancing the sheet resistance of an optical area cathode electrode by disposing a cathode hole to form a transmissive area.

Exemplary embodiments of the disclosure may provide a display device comprising a substrate including a normal area including a plurality of first emission areas and an optical area including a plurality of second emission areas and a plurality of transmissive areas, a circuit layer disposed on the substrate, a pixel electrode disposed on the circuit layer, a light emitting layer disposed on the pixel electrode, a common electrode disposed on the light emitting layer, a conductive material layer disposed on the common electrode, and a transparent electrode disposed on the conductive material layer.

Exemplary embodiments of the disclosure may provide a display device comprising a substrate, a circuit layer disposed on the substrate, a pixel electrode disposed on the circuit layer, a light emitting layer disposed on the pixel electrode, a common electrode disposed on the light emitting layer, an encapsulation layer disposed on the common electrode, a metal layer disposed between the common electrode and the encapsulation layer, and an organic layer or an inorganic layer disposed between the common electrode and the metal layer.

Exemplary embodiments of the disclosure may provide a display device comprising a substrate including a normal area including a plurality of first emission areas and an optical area including a plurality of second emission areas and a plurality of transmissive areas; a first electrode disposed over the substrate; a conductive material layer disposed on the first electrode; and a transparent electrode disposed on the conductive material layer.

According to an exemplary embodiment of the disclosure, it is possible to reduce the sheet resistance of the cathode electrode disposed in the optical area where an electronic device is disposed. Accordingly, there may be provided a display device with enhanced luminous efficiency and the ability to deliver uniform luminance at low power consumption.

According to exemplary embodiments of the disclosure, there may be provided a display device capable of reducing a luminance deviation between the optical area where an electronic device is disposed and an area other than the optical area.

According to exemplary embodiments of the disclosure, there may be provided a display device capable of enhancing the transmittance of the light emitted from a light emitting element.

According to exemplary embodiments of the disclosure, there may be provided a display device capable of enhancing the sheet resistance of an optical area cathode electrode by forming a transmissive area without disposing a cathode hole.

According to exemplary embodiments of the disclosure, there may be provided a display device capable of enhancing the sheet resistance of an optical area cathode electrode by disposing a cathode hole to form a transmissive area.

Specific details according to the various examples of the present disclosure other than solutions to the above-mentioned problems are included in the description and drawings described below.

### BRIEF DESCRIPTION OF DRAWINGS

The above and other objects, features, and advantages of the disclosure will be more clearly understood from the following detailed description, taken in conjunction with the accompanying drawings, in which:

FIGS. 1A, 1B, and 1C illustrate a display device according to exemplary embodiments of the disclosure;

FIG. 2 is a view illustrating a configuration of a system of a display device according to exemplary embodiments of the disclosure;

FIG. 3 is a view schematically illustrating a display panel according to exemplary embodiments of the disclosure;

FIG. 4 is an enlarged plan view illustrating a partial area of a display panel according to exemplary embodiments of the disclosure;

FIG. 5 is a cross-sectional view taken along dashed line A-A′ of the normal area of FIG. 4 and along dashed line B-B′ of the optical area according to exemplary embodiments of the disclosure;

FIG. 6 is a view schematically illustrating a resistance enhancement structure according to exemplary embodiments of the disclosure;

FIG. 7 is a graph illustrating the work function and lowest unoccupied molecular orbital values of components of a resistance enhancement structure according to exemplary embodiments of the disclosure;

FIG. 8 is a view schematically illustrating a structure in which a resistance enhancement structure is disposed when a cathode electrode is disposed in a transmissive area in a display area according to exemplary embodiments of the disclosure;

FIG. 9 is a cross-sectional view illustrating an optical area in which a resistance enhancement structure is disposed according to the exemplary embodiment of FIG. 8;

FIG. 10 is a cross-sectional view illustrating a normal area adjacent to the optical area shown in the cross-sectional view of FIG. 9 according to exemplary embodiments of the disclosure;

FIG. 11 is a graph comparing the transmittance between an emission area where a resistance enhancement structure is disposed and an emission area where a resistance enhancement structure is not disposed according to exemplary embodiments of the disclosure;

FIG. 12 is a view schematically illustrating a structure in which a resistance enhancement structure is disposed when a cathode electrode is not disposed in a transmissive area in a display area according to exemplary embodiments of the disclosure;

FIG. 13 is a cross-sectional view illustrating an optical area in which a resistance enhancement structure is disposed according to the exemplary embodiment of FIG. 12;

FIG. 14 is a cross-sectional view illustrating an optical area in which a resistance enhancement structure and a touch sensor are disposed according to exemplary embodiments of the disclosure; and

FIG. 15 is a graph illustrating a resistance enhancement effect according to exemplary embodiments of the disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “include,” “have,” “comprise,” “contain,” “constitute,” “make up of,” “formed of,” and “consist of” used herein are generally intended to allow other components to be added unless the terms are used with the term “only”. As used herein, singular forms are intended to include plural forms unless the context clearly indicates otherwise.

Since the shapes, sizes, dimensions (e.g., length, width, height, thickness, radius, diameter, area, etc.), ratios, angles, numbers, and the like disclosed in the drawings for describing the embodiments of the present disclosure are only exemplary, the present disclosure is not limited to the items shown in the drawings.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

In a description of a positional relationship, when the positional relationship of two parts such as “on”, “above”, “over”, “below”, “under”, “beside”, “beneath”, “near”, “close to,” “adjacent to”, “on a side of”, “next” or the like is described, one or more other parts may be located between two components unless “immediately”, “directly,” “close to” is used.

It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

When it is mentioned that a first element “is connected or coupled to”, “contacts or overlaps” etc. a second element, it may be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it may be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

“At least one” should be understood as including a combination of one or more of the related components. For example, the term “at least one of first, second, and third components” includes not only the first, second, or third component, but also all combinations of two or more of the first, second, and third components.

The terms “first direction,” “second direction,” “third direction,” “X-axis direction,” “Y-axis direction,” and “Z-axis direction” should not be understood as only a geometric relationship in which a relationships therebetween are perpendicular to each other, but mean that a configuration of the present disclosure has a broader directionality within a range in which it may functionally act.

A term “device” used herein may refer to a display device including a display panel and a driver for driving the display panel. Examples of the display device may include a light emitting element, and the like. In addition, examples of the device may include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

Features of various exemplary embodiments of the present disclosure may be partially or entirely combined with each other, and technically, various linkages and operations are possible, and the exemplary embodiments may be implemented independently of each other or together in a related relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode may be the drain electrode, and the drain electrode may be the source electrode. Also, the source electrode in any one aspect of the present disclosure may be the drain electrode in another aspect of the present disclosure, and the drain electrode in any one aspect of the present disclosure may be the source electrode in another aspect of the present disclosure.

Hereinafter, various exemplary embodiments of the disclosure are described in detail with reference to the accompanying drawings.

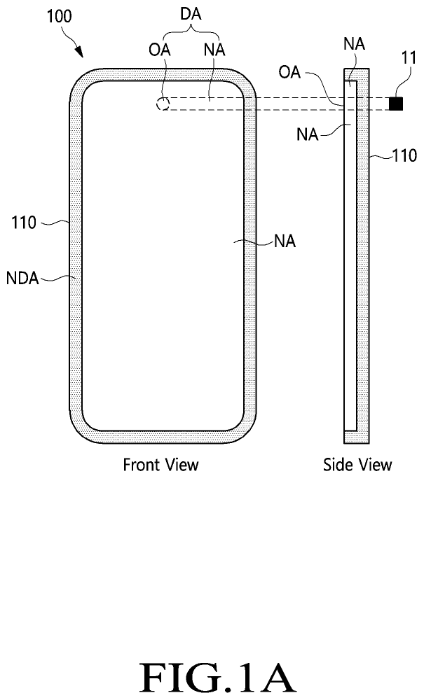

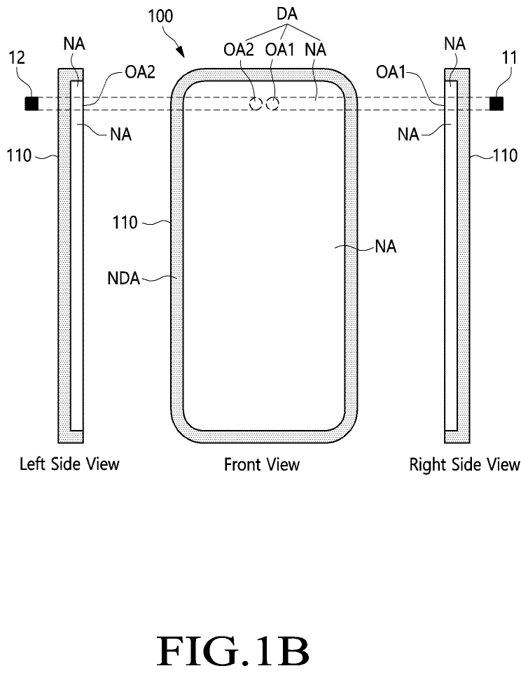

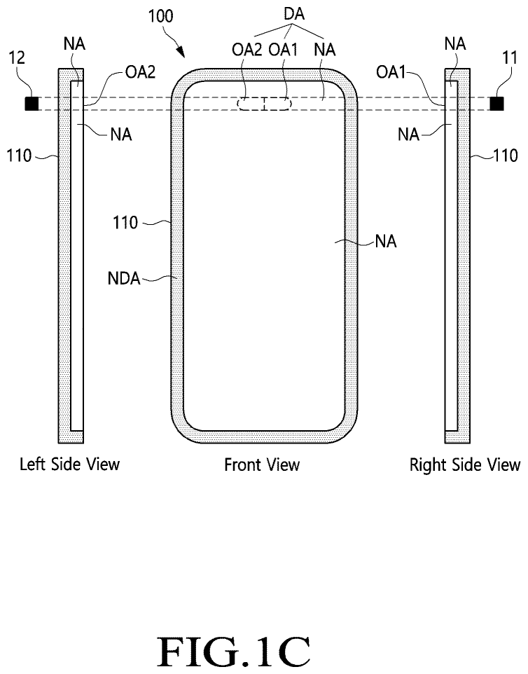

FIGS. 1A, 1B, and 1C illustrate a display device 100 according to exemplary embodiments of the disclosure.

Referring to FIGS. 1A, 1B, and 1C, a display device 100 according to exemplary embodiments of the disclosure may include a display panel 110 for displaying images and one or more optical electronic devices 11 and 12.

The display panel 110 may include a display area DA in which images (videos) may displayed and a non-display area NDA in which no image is displayed.

A plurality of subpixels may be disposed in the display area DA, and various signal lines for driving the plurality of subpixels may be disposed in the display area AA.

The non-display area NDA may be an area outside the display area DA. In the non-display area NDA, various signal lines may be disposed, and various driving circuits may be connected thereto. The non-display area NDA may be bent to be invisible from the front or may be covered by a case (not shown). The non-display area NDA is also referred to as a bezel or a bezel area. The non-display area NDA may include a pad area located outside of (e.g., spaced apart from) the display area AA in a column direction. For example, the pad area may be a portion of the non-display area NDA.

For example, the non-display area NDA may include a first non-display area, a second non-display area, a third non-display area, and a fourth non-display area. The first non-display area may be located outside of the display area AA in the column direction. The second non-display area may be located outside of the display area AA in a row direction. The third non-display area may be located outside of the display area AA in the column direction and located opposite to the first non-display area. The fourth non-display area may be located outside of the display area AA in the row direction and located opposite to the second non-display area. The first non-display area among the first to fourth non-display areas may include a pad area to which a driving circuit is connected or bonded. The second to fourth non-display areas that do not include the pad area among the first to fourth non-display areas may have a very small size, but aspects of the present disclosure are not limited thereto.

In one or more embodiments, a boundary area between the display area AA and the non-display area NDA may be bent, and in this structure, the non-display area NDA may be located under the display area DA.

Referring to FIGS. 1A, 1B, and 1C, in the display device 100 according to exemplary embodiments of the disclosure, one or more optical electronic devices 11 and 12 are electronic components that are provided and installed separately from the display panel 110 and positioned under the display panel 110 (side opposite to the viewing surface).

Light enters the front surface (viewing surface) of the display panel 110 and passes through the display panel 110 to one or more optical electronic devices 11 and 12 positioned under the display panel 110 (opposite to the viewing surface). For example, the light passing through the display panel 110 may include visible light, infrared light, or ultraviolet light.

The one or more optical electronic devices 11 and 12 may be devices that receive the light transmitted through the display panel 110 and perform a predetermined function according to the received light. For example, the one or more optical electronic devices 11 and 12 may include one or more of a capture device, such as a camera (image sensor), and a detection sensor, such as a proximity sensor and an illuminance sensor. For example, the detection sensor may be an infrared sensor.

Referring to FIGS. 1A, 1B, and 1C, in the display panel 110 according to exemplary embodiments of the disclosure, the display area DA may include a normal area NA and one or more optical areas OA1 and OA2. The one or more optical areas OA1 and OA2 may be areas overlapping the one or more optical electronic devices 11 and 12.

According to the example of FIG. 1A, the display area DA may include the normal area NA and the first optical area OA1. At least a portion of the first optical area OA1 may overlap the first optical electronic device 11.

According to the example of FIG. 1B, the display area DA may include a normal area NA, a first optical area OA1, and a second optical area OA2. In the example of FIG. 1B, the normal area NA may be present between the first optical area OA1 and the second optical area OA2. At least a portion of the first optical area OA1 may overlap the first optical electronic device 11, and at least a portion of the second optical area OA2 may overlap the second optical electronic device 12, but the present disclosure is not limited thereto.

According to the example of FIG. 1C, the display area DA may include a normal area NA, a first optical area OA1, and a second optical area OA2. In the example of FIG. 1C, the normal area NA is not present between the first optical area OA1 and the second optical area OA2. In other words, the first optical area OA1 and the second optical area OA2 touch each other. At least a portion of the first optical area OA1 may overlap the first optical electronic device 11, and at least a portion of the second optical area OA2 may overlap the second optical electronic device 12.

The one or more optical areas OA1 and OA2 may have both an image display structure and a light transmission structure. In other words, since the one or more optical areas OA1 and OA2 are partial areas of the display area DA, emission areas of subpixels for displaying images may be disposed in the one or more optical areas OA1 and OA2. A light transmission structure for transmitting light to the one or more optical and electronic devices 11 and 12 may be formed in one or more optical areas OA1 and OA2.

The one or more optical electronic devices 11 and 12 are devices that require light reception, but are positioned behind (below, opposite to the viewing surface) the display panel 110 to receive the light transmitted through the display panel 110. The one or more optical electronic devices 11 and 12 are not exposed on the front surface (viewing surface) of the display panel 110. Therefore, when the user looks at the front surface of the display device, the optical electronic devices 11 and 12 are not visible to the user.

For example, the first optical electronic device 11 may be a camera, and the second optical electronic device 12 may be a detection sensor, such as a proximity sensor or an illuminance sensor. For example, the detection sensor may be an infrared sensor that detects infrared rays. Conversely, the first optical electronic device 11 may be a detection sensor, and the second optical electronic device 12 may be a camera, but the present disclosure is not limited thereto.

Hereinafter, for convenience of description, it is assumed that the first optical electronic device 11 is a camera and the second electronic device 12 is an infrared (IR)-based detection sensor. The camera may be a camera lens or an image sensor.

If the first optical electronic device 11 is a camera, the camera may be a front camera that is positioned behind (below) the display panel 110 but captures forward of the display panel 110. Accordingly, the user may take a photograph through the camera invisible to the viewing surface while viewing the viewing surface of the display panel 110.

The normal area NA and one or more optical areas OA1 and OA2 included in the display area DA are areas that may display images, but the normal area NA is an area that does not require a light transmission structure to be formed, and the one or more optical areas OA1 and OA2 are areas that require a light transmission structure to be formed.

Accordingly, the one or more optical areas OA1 and OA2 may have a transmittance higher than or equal to a certain level, and the normal area NA may have no light transmittance or a lower transmittance less than the certain level. For example, a light transmittance of each of the one or more optical areas OA1 and OA2 is greater than a light transmittance of the normal area NA.

For example, one or more optical areas OA1 and OA2 and the normal area NA may have different resolutions, subpixel placement structures, numbers of subpixels per unit area, electrode structures, line structures, electrode placement structures, or line placement structures.

For example, the number of subpixels per unit area in one or more optical areas OA1 and OA2 may be smaller (less) than the number of subpixels per unit area in the normal area NA. In other words, the resolution of one or more optical areas OA1 and OA2 may be lower than the resolution of the normal area NA. Here, the number of subpixels per unit area may be meant to be equivalent to resolution, or pixel density, or pixel integration degree. For example, the unit for the number of subpixels per unit area may be pixels per inch (PPI), which means the number of pixels in one inch.

For example, the number of subpixels per unit area in the first optical area OA1 may be smaller than the number of subpixels per unit area in the normal area NA. The number of subpixels per unit area in the second optical area OA2 may be larger than or equal to the number of subpixels per unit area in the first optical area OA1 and be smaller than the number of subpixels per unit area in the normal area NA.

Meanwhile, as one method for increasing the transmittance of at least one of the first optical area OA1 and the second optical area OA2, a pixel density differential design scheme may be applied as described above. According to the pixel density differential design scheme, the display panel 110 may be designed so that the number of subpixels per unit area of at least one of the first optical area OA1 and the second optical area OA2 is larger than the number of subpixels per unit area of the normal area NA. For example, the number of subpixels per unit area of the first optical area OA1 or the second optical area OA2 is larger than the number of subpixels per unit area of the normal area NA. Alternatively, the number of subpixels per unit area of each of the first optical area OA1 and the second optical area OA2 is larger than the number of subpixels per unit area of the normal area NA.

However, in some cases, as another method for increasing the transmittance of at least one of the first optical area OA1 and the second optical area OA2, a pixel size differential design scheme may be applied. According to the pixel size differential design scheme, the display panel 110 may be designed so that the number of subpixels per unit area of at least one of the first optical area OA1 and the second optical area OA2 is identical or similar to the number of subpixels per unit area of the normal area NA, and the size of each subpixel (e.g., the size of the emission area) disposed in at least one of the first optical area OA1 and the second optical area OA2 is smaller than the size of each subpixel SP (e.g., the size of the emission area) disposed in the normal area NA. For example, the size of each subpixel (e.g., the size of the emission area) disposed in the first optical area OA1 or the second optical area OA2 is smaller than the size of each subpixel SP (e.g., the size of the emission area) disposed in the normal area NA. Alternatively, the size of each subpixel (e.g., the size of the emission area) disposed in each of the first optical area OA1 and the second optical area OA2 is smaller than the size of each subpixel SP (e.g., the size of the emission area) disposed in the normal area NA.

Hereinafter, for convenience of description, it is assumed in the following description that, of the two schemes (pixel density differential design scheme and pixel size differential design scheme) for increasing the transmittance of at least one of the first optical area OA1 and the second optical area OA2, the pixel density differential design scheme is applied. Accordingly, that the number of subpixels per unit area is small, as described below, may be an expression corresponding to the subpixel size being small, and that the number of subpixels per unit area is large may be an expression corresponding to the subpixel size being large.

The first optical area OA1 may have various shapes, such as a circle, an ellipse, a quadrangle, a hexagon, or an octagon. The second optical area OA2 may have various shapes, such as a circle, an ellipse, a square, a hexagon, or an octagon. The first optical area OA1 and the second optical area OA2 may have the same shape or different shapes.

Referring to FIG. 1C, when the first optical area OA1 and the second optical area OA2 are in contact, the entire optical area including the first optical area OA1 and the second optical area OA2 may have various shapes, such as a circle, an ellipse, a square, a hexagon, or an octagon. Hereinafter, for convenience of description, each of the first optical area OA1 and the second optical area OA2 is exemplified as having a circular shape.

In the display device 100 according to exemplary embodiments of the disclosure, if the first optical electronic device 11 that is not exposed to the outside and is hidden in a lower portion of the display panel 110 is a camera, the display device 100 according to exemplary embodiments of the disclosure may be referred to as a display to which under display camera (UDC) technology has been applied.

Accordingly, the display device 100 according to exemplary embodiments of the disclosure does not require a notch or camera hole for camera exposure to be formed in the display panel 110, thereby preventing a reduction in the display area DA. Thus, as there is no need to form a notch or camera hole for exposure of the camera in the display panel 110, the size of the bezel area may be reduced, and design restrictions may be freed, thereby increasing the degree of freedom in design.

In the display device 100 according to exemplary embodiments of the disclosure, although one or more optical electronic devices 11 and 12 are positioned to be hidden behind the display panel 110, one or more optical electronic devices 11 and 12 is able to normally perform predetermined functions by normally receiving light.

Further, in the display device 100 according to exemplary embodiments of the disclosure, although one or more optical electronic devices 11 and 12 are positioned to be hidden behind the display panel 110 and are positioned to overlap the display area DA, the one or more optical areas OA1 and OA2 overlapping the one or more optical electronic devices 11 and 12 in the display area DA is capable of normal image display.

Since the above-mentioned first optical area OA1 is designed as a transmittable area, the image display characteristics in the first optical area OA1 may differ from the image display characteristics in the normal area NA.

Further, in designing the first optical area OA1 to enhance the image display characteristics, the transmittance of the first optical area OA1 may be degraded, but the present disclosure is not limited thereto.

Accordingly, exemplary embodiments of the disclosure propose a structure of the first optical area OA1 capable of enhancing transmittance in the first optical area OA1 without causing an image quality deviation between the first optical area OA1 and the normal area NA.

Further, in addition to the first optical area OA1, exemplary embodiments of the disclosure further propose a structure of the second optical area OA2 capable of enhancing transmittance in the second optical area OA2 and image quality in the second optical area OA2 for the second optical area OA2.

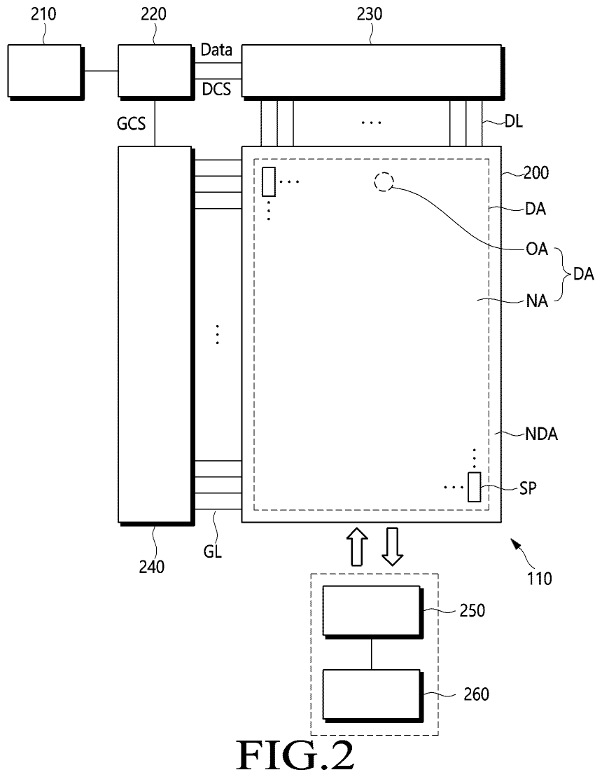

FIG. 2 is a view illustrating a system configuration of a display device 100 according to exemplary embodiments of the disclosure.

Referring to FIG. 2, a display device 100 may include a display panel 110 and display driving circuits, as components for displaying images.

The display driving circuits are circuits for driving the display panel 110 and may include a data driving circuit 230, a gate driving circuit 240, and a display controller 220.

The display panel 110 may include a display area DA in which images are displayed and a non-display area NDA in which no image is displayed. The non-display area NDA may be an outer area of the display area DA and be referred to as a bezel area. The whole or part of the non-display area NDA may be an area visible from the front surface of the display device 100 or an area that is bent and not visible from the front surface of the display device 100.

The display panel 110 may include a substrate 200 and a plurality of subpixels SP disposed on the substrate 200. The display panel 110 may further include various types of signal lines to drive the plurality of subpixels SP.

The display device 100 according to exemplary embodiments of the disclosure may be a self-emission display device in which the display panel 110 emits light by itself. However, the display device 100 according to exemplary embodiments of the disclosure is not limited to a self-luminous display device. When the display device 100 according to the exemplary embodiments of the disclosure is a self-emission display device, each of the plurality of subpixels SP may include a light emitting element. For example, the display device 100 according to exemplary embodiments of the disclosure may be an organic light emitting diode display device in which the light emitting element is implemented as an organic light emitting diode (OLED). As another example, the display device 100 according to exemplary embodiments of the disclosure may be an inorganic light emitting display device in which the light emitting element is implemented as an inorganic material-based light emitting diode. As another example, the display device 100 according to exemplary embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

The transistor may be implemented as a thin film transistor (TFT). Active layers of the thin-film transistors TFTs may be formed of a semiconductor material, such as an oxide semiconductor, amorphous semiconductor, or polycrystalline semiconductor, but is not limited thereto.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed while extending in a first direction. Each of the plurality of gate lines GL may be disposed while extending in a second direction. Here, the first direction may be a column direction and the second direction may be a row direction. The first direction may be the row direction, and the second direction may be the column direction.

The data driving circuit 230 is a circuit for driving the plurality of data lines DL, and may output data signals to the plurality of data lines DL. The gate driving circuit 240 is a circuit for driving the plurality of gate lines GL, and may output gate signals to the plurality of gate lines GL.

The display controller 220 is a device for controlling the data driving circuit 230 and the gate driving circuit 240 and may control driving timings for the plurality of data lines DL and driving timings for the plurality of gate lines GL.

The display controller 220 may supply a data driving control signal DCS to the data driving circuit 230 to control the data driving circuit 230 and may supply a gate driving control signal GCS to the gate driving circuit 240 to control the gate driving circuit 240.

The driving circuit of the display panel 110 may be driven at a variable refresh rate (VRR) under the control of the display controller 220. For example, the display controller 220 may analyze an input image and reduce the power consumption of the display device by lowering the refresh rate when the input image does not change for a predetermined amount of time. In this case, the driving circuit of the display panel 110 may reduce the power consumption of the display device by controlling a data writing cycle of the pixels PXL to be longer by lowering the refresh rate of the pixels PXL when a still image is input for a certain period of time or longer under the control of the display controller 220. The refresh rate of the driving circuit of the display panel 110 may be lower when the display device is operated in standby mode or in response to a user command. In addition, the refresh rate may be lower on an Always On Display (AOD) screen. The AOD screen is a partial pixel area of the display area AA in which the predetermined information, for example brief information such as remaining battery power, time, etc. is displayed in standby mode. The refresh rate may be interpreted as a driving frequency of the pixels PXL for updating data of the pixels.

The display controller 220 may control the operation timing of the data driving circuit 230 and the gate driving circuit 240 of the display panel 110 at a frame frequency of an input frame frequency×i Hz by multiplying the frame frequency of the input image by a factor of i (i is a natural number). The display controller 220 may support variable refresh rates. For example, the display controller 220 may lower the driving frequency of the pixels PXL to a frequency between 1 Hz and 30 Hz in a low-speed driving mode to lower the refresh rate of the pixels PXL.

The display controller 220 may receive input image data from the host system 210 and supply image data Data to the data driving circuit 230 based on the input image data.

The host system 210, which is applied to the display controller 220, may be one of a television (TV) system, a set-top box, a navigation system, a personal computer (PC), a home theater system, a mobile appliance, a wearable appliance, and a vehicle system.

The data driving circuit 230 may receive digital image data Data from the display controller 220 and may convert the received image data Data into analog data signals and output the analog data signals to the plurality of data lines DL.

The gate driving circuit 240 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

For example, the data driving circuit 230 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 240 may be connected with the display panel 110 by TAB method or connected to a bonding pad of the display panel 110 by a COG or COP method or may be connected with the display panel 110 according to a COF method. Alternatively, the gate driving circuit 240 may be formed in a gate in panel (GIP) type, in the non-display area NDA of the display panel 110. The gate driving circuit 240 may be disposed on the substrate or may be connected to the substrate. In other words, the gate driving circuit 240 that is of a GIP type may be disposed in the non-display area NDA of the substrate. The gate driving circuit 240, which is of a chip-on-glass (COG) type or chip-on-film (COF) type may be connected to the substrate.

Meanwhile, at least one of the data driving circuit 230 and the gate driving circuit 240 may be disposed in the display area DA of the display panel 110. For example, at least one of the data driving circuit 230 and the gate driving circuit 240 may be disposed not to overlap the subpixels SP or to overlap all or some of the subpixels SP.

The data driving circuit 230 may be connected to one side (e.g., an upper or lower side) of the display panel 110. Depending on the driving scheme or the panel design scheme, data driving circuits 230 may be connected with both the sides (e.g., both the upper and lower sides) of the display panel 110, or two or more of the four sides of the display panel 110, but the present disclosure is not limited thereto.

The gate driving circuit 240 may be connected to one side (e.g., a left or right side) of the display panel 110. Depending on the driving scheme or the panel design scheme, gate driving circuits 240 may be connected with both the sides (e.g., both the left and right sides) of the display panel 110, or two or more of the four sides of the display panel 110, but the present disclosure is not limited thereto.

The display controller 220 may be implemented as a separate component from the data driving circuit 230, or the display controller 220 and the data driving circuit 230 may be integrated into an integrated circuit (IC).

The display controller 220 may be a timing controller used in typical display technology, a control device that may perform other control functions as well as the functions of the timing controller, or a control device other than the timing controller, or may be a circuit in the control device. The display controller 220 may be implemented as various circuits or electronic components, such as an integrated circuit (IC), a field programmable gate array (FPGA), an application specific integrated circuit (ASIC), or a processor.

The display controller 220 may be mounted on a printed circuit board or a flexible printed circuit and may be electrically connected with the data driving circuit 230 and the gate driving circuit 240 through the printed circuit board or the flexible printed circuit.

The display controller 220 may transmit/receive signals to/from the data driving circuit 230 according to one or more predetermined interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to exemplary embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit 250 that drives and senses the touch sensor and generates and outputs touch sensing data and a touch controller 260 that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit 250.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate 200, together with signal lines and electrodes related to display driving, during the manufacturing process of the display panel 110.

The touch driving circuit 250 may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit 250 may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit 250 may drive the driving touch electrodes and sense the sensing touch electrodes.

The touch driving circuit 250 and the touch controller 260 included in the touch sensing circuit may be implemented as separate devices or as a single device. The touch driving circuit 250 and the data driving circuit 230 may be implemented as separate devices or as a single device.

The display device 100 may further include a power supply circuit for supplying various types of power to the display driver integrated circuit and/or the touch sensing circuit.

The display device 100 according to exemplary embodiments of the disclosure may be a mobile terminal, such as a smart phone or a tablet, or a monitor or television (TV) in various sizes but, without limited thereto, may be a display in various types and various sizes capable of displaying information or images.

As described above, the display area DA in the display panel 110 may include the normal area NA and one or more optical areas OA1 and OA2. The normal area NA and one or more optical areas OA1 and OA2 are areas capable of displaying an image. However, the normal area NA is an area where a light transmission structure is not required to be formed, and one or more optical areas OA1 and OA2 are areas in which a light transmission structure is to be formed.

As described above, the display area DA in the display panel 110 may include one or more optical areas OA1 and OA2 together with the normal area NA, but for convenience of description, it is assumed that the display area DA includes only one first optical area OA1 (FIG. 1A). In the following description, the first optical area OA1 may have the same meaning as the optical area OA. Meanwhile, the number of the optical areas OA is not limited to one or two, it may also be three or more.

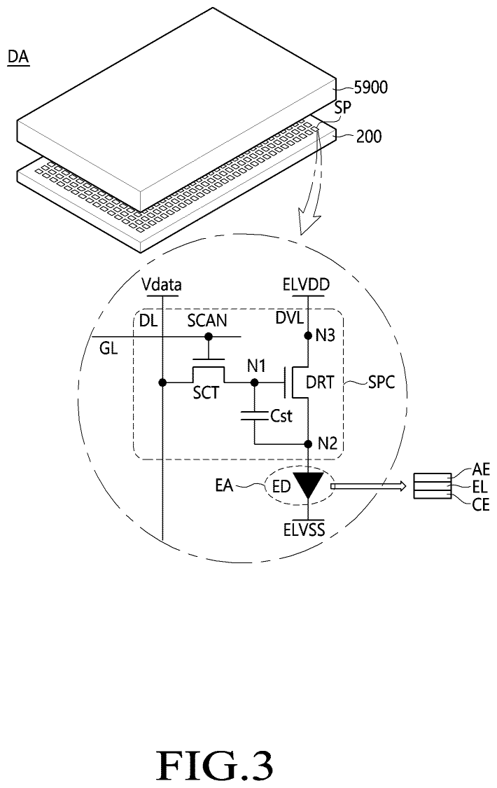

FIG. 3 is a view schematically illustrating a display panel 110 according to exemplary embodiments of the disclosure.

Referring to FIG. 3, a plurality of subpixels SP may be disposed in the display area DA of the display panel 110. The plurality of subpixels SP may be disposed in the normal area NA and the optical area OA included in the display area DA.

Each of the plurality of subpixels is a minimum unit which configures the display area and n subpixels form one pixel. Each of the plurality of subpixels may emit light having different wavelengths from each other. The plurality of subpixels may include first to third subpixels which emit different color light from each other. For example, each of the pixels PXL may be divided into a red sub-pixel, a green sub-pixel, and a blue sub-pixel for color implementation. Each of the pixels may further include a white sub-pixel. The plurality of subpixels may be variously modified in colors and configurations, as necessary. However, the present disclosure is not limited thereto.

For example, the plurality of subpixels may include red, green, and blue subpixels, in which the red, green, and blue subpixels may be disposed in a repeated manner. Alternatively, the plurality of subpixels may include red, green, blue, and white subpixels, in which the red, green, blue, and white subpixels may be disposed in a repeated manner, or the red, green, blue, and white subpixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the subpixels are not limiting, and may be configured in various forms according to light-emitting characteristics, device lifespans, and device specifications.

Meanwhile, the subpixels may have different light-emitting areas according to light-emitting characteristics. For example, a subpixel that emits light of a color different from that of a blue subpixel may have a different light-emitting area from that of the blue subpixel. For example, the red subpixel, the blue subpixel, and the green subpixel, or the red subpixel, the blue subpixel, the white subpixel, and the green subpixel may each has a different light-emitting area.

Referring to FIG. 3, each of the plurality of subpixels SP may include a light emitting element ED and a pixel circuit SPC configured to drive the light emitting element ED.

Referring to FIG. 3, the pixel circuit SPC may include a driving transistor DRT for driving the light emitting element ED, a scan transistor SCT for transferring the data voltage Vdata to the first node N1 of the driving transistor DRT, and a storage capacitor Cst for maintaining a constant voltage during one frame.

The driving transistor DRT may include the first node N1 to which the data voltage may be applied, a second node N2 electrically connected with the light emitting element ED, and a third node N3 to which a driving voltage ELVDD is applied from a driving voltage line DVL. The first node N1 in the driving transistor DRT may be a gate node, the second node N2 may be a source node or a drain node, and the third node N3 may be the drain node or the source node. For convenience of description, described below is an example in which the first node N1 in the driving transistor DRT is a gate node, the second node N2 is a source node, and the third node N3 is a drain node.

The light emitting element ED may include an anode electrode AE, a light emitting layer EL, and a cathode electrode CE. The anode electrode AE may be a pixel electrode disposed in each subpixel SP and be electrically connected to the second node N2 of the driving transistor DRT of each subpixel SP. The cathode electrode CE may be a common electrode commonly disposed in the plurality of subpixels SP, and a base voltage ELVSS may be applied thereto.

For example, the anode electrode AE may be a pixel electrode, and the cathode electrode CE may be a common electrode. Conversely, the anode electrode AE may be a common electrode, and the cathode electrode CE may be a pixel electrode. Hereinafter, for convenience of description, it is assumed that the anode electrode AE is a pixel electrode and the cathode electrode CE is a common electrode.

The light emitting element ED may have a predetermined emission area EA. The emission area EA of the light emitting element ED may be defined as an area where the anode electrode AE, the light emitting layer EL, and the cathode electrode CE overlap.

For example, the light emitting element ED may be an organic light emitting diode (OLED), an inorganic light emitting diode, or a quantum dot light emitting element. When the light emitting element ED is an organic light emitting diode, the light emitting layer EL of the light emitting element ED may include an organic light emitting layer EL including an organic material.

The scan transistor SCT may be on/off controlled by a scan signal SCAN, which is a gate signal, applied via the gate line GL and be electrically connected between the first node N1 of the driving transistor DRT and the data line DL.

The storage capacitor Cst may be electrically connected between the first node N1 and second node N2 of the driving transistor DT.

The pixel circuit SPC may have a 2T (transistor) 1C (capacitor) structure which includes two transistors DT and ST and one capacitor Cst as shown in FIG. 3 and, in some cases, each subpixel SP may further include one or more transistors or one or more capacitors. However, the pixel circuit of each of the plurality of subpixels are not limited thereto, each of the plurality of subpixels may further include a compensation circuit. In this case, each of the plurality of subpixels may have various structures such as 4T2C, 5T2C, 6TIC, 6T2C, 7TIC, 7T2C, and the like.

The capacitor Cst may be an external capacitor intentionally designed to be outside the driving transistor DRT, but not a parasite capacitor (e.g., Cgs or Cgd) which is an internal capacitor that may be present between the first node N1 and the second node N2 of the driving transistor DT. Each of the driving transistor DRT and the scan transistor SCT may be an n-type transistor or a p-type transistor.

Since the circuit elements (especially the light emitting element ED implemented as an organic light emitting diode (OLED) including an organic material) in each subpixel SP are vulnerable to external moisture or oxygen, the encapsulation layer 5900 for preventing external moisture or oxygen from penetrating into the circuit elements (especially the light emitting element ED) may be disposed on the display panel 110. The encapsulation layer 5900 may be disposed to cover the light emitting elements ED.

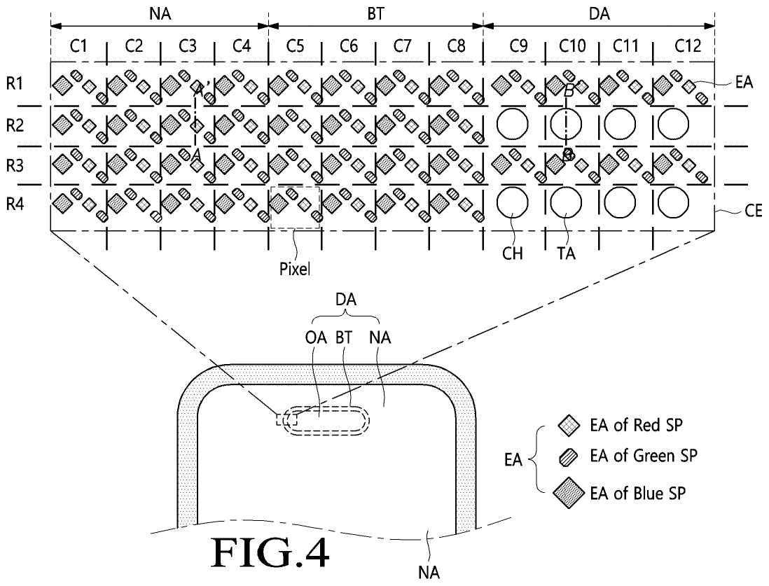

FIG. 4 is an enlarged plan view illustrating a partial area of a display panel 110 according to exemplary embodiments of the disclosure.

The display panel 110 according to exemplary embodiments of the disclosure may include a normal area NA and an optical area OA, as described above with reference to FIGS. 1 and 2. Further, a boundary area BT may be further included between the normal area NA and the optical area OA.

The configuration of the boundary area BT may be the same as the configuration of the normal area NA. Further, the width of the boundary area BT may be variously set. The boundary area BT may be adjacent to the normal area NA and the optical area OA.

The optical area OA may include a plurality of transmissive areas TA. Referring to FIG. 4, the transmissive areas TA may be disposed in a plurality of circular shapes in the optical area OA. Further, the transmissive areas TA may be disposed in even-numbered rows R2 and R4 of the optical area OA. However, this is merely an example for convenience of description, and the shape or arrangement of the transmissive areas TA is not limited thereto. For example, the transmissive area may have a polygonal shape such as a rectangle or a hexagon, and may be disposed in various forms, such as being disposed in even-numbered columns C10 and C12, or alternately disposed in even-numbered matrixes C10R2, C10R4, C12R2, and C12R4. However, the present disclosure is not limited thereto.

In an exemplary embodiment of the disclosure, for convenience of description, it is assumed that a set of one red subpixel EA of Red SP, two green subpixels EA of Green SP, and one blue subpixel EA of Blue SP is a pixel. The configuration of each subpixel included in one pixel is merely an example for convenience of description, but is not limited thereto.

The pixel may be disposed in the normal area NA, the boundary area BT, and the optical area OA. Referring to FIG. 4, pixels as many as 4 rows and 4 columns may be disposed in each of the enlarged normal area NA and the boundary area BT. However, four rows and four columns are assumed for convenience of description, and in particular, the width of the boundary area BT is not limited to the number of matrixes.

Further, in the optical area OA, the pixels as many as two rows and four columns which correspond to the area which does not overlap the transmissive area TA may be disposed. For example, referring to FIG. 4, the pixels may be disposed in odd-numbered rows R1 and R3 so as not to overlap the transmissive area TA disposed in the even-numbered rows R2 and R4. However, the form where the pixel and the transmissive area TA are disposed is not limited thereto.

Referring to FIG. 4, the cathode electrode CE is disposed on the entire surface of the display area DA including the normal area NA, the boundary area BT, and the optical area OA, and in the optical area OA, a cathode hole CH may be formed in an area corresponding to the transmissive area TA. In other words, the cathode electrode CE may form the cathode hole CH in the even-numbered rows R2 and R4 corresponding to the transmissive area TA in the optical area OA.

Referring to FIG. 4, the cathode hole CH is disposed to overlap the transmissive area TA. The pixel is disposed not to overlap the transmissive area TA. Therefore, the cathode hole CH and the pixel may not overlap each other.

Meanwhile, as the cathode electrode CE of the optical area OA forms the cathode hole CH, the area of the cathode electrode CE may be decreased, and thus the sheet resistance may increase. The cathode electrode CE of the boundary area BT adjacent to the optical area OA may have a relatively decreased sheet resistance. As the sheet resistance of the cathode electrode CE of the optical area OA increases and the sheet resistance of the cathode electrode CE of the boundary area BT decreases relatively, the luminance of pixels disposed in the areas may become non-uniform.

In other words, when a cathode hole CH forms in the cathode electrode CE, the sheet resistance of the pixel in the optical area OA may increase, potentially leading to a decrease in luminance. As the sheet resistance of the pixel of the boundary area BT adjacent to the optical area OA is relatively decreased, the luminance of the cathode electrode CE of the pixel may increase. Therefore, referring to FIG. 4, the luminance of the pixel may decrease as the sheet resistance of the cathode electrode CE increases from column C5 to column C12 in the enlarged plan view. Conversely, as the sheet resistance of the cathode electrode CE decreases from the column C12 to the column C5, the luminance of the pixel may increase.

Consequently, a luminance unevenness issue may arise between the optical area OA and the boundary area BT as the luminance of the OA pixel decreases and the luminance of the BT pixel increases.

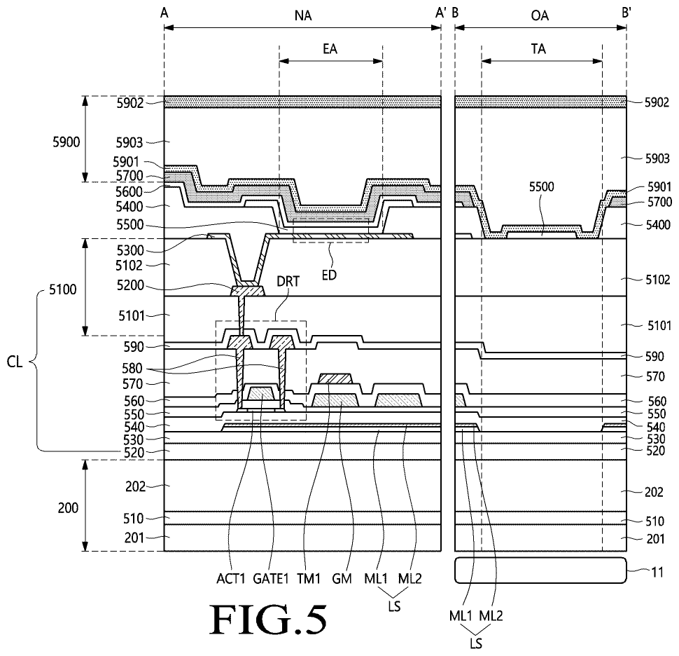

FIG. 5 is a cross-sectional view taken along dashed line A-A′ of the normal area NA of FIG. 4 and along dashed line B-B′ of the optical area OA according to one embodiment.

First, referring to FIG. 5, the stacked structure of the normal area NA and the optical area OA is described.

First, a stacked structure for the optical area OA is described with reference to FIG. 5.

Referring to FIG. 5, the substrate SUB may include a first substrate 201, an interlayer insulation film 510, and a second substrate 202. The interlayer insulation film 510 may be positioned between the first substrate 201 and the second substrate 202. By configuring the substrate 200 with the first substrate 201, the interlayer insulation film IPD and the second substrate 202, it is possible to prevent or reduce moisture penetration. For example, the first substrate 201 and the second substrate 202 may include a flexible polymer film. For example, the flexible polymer film may be made of any one of polyimide (PI), polyethylene terephthalate (PET), acrylonitrile-butadiene-styrene copolymer(ABS), polymethyl methacrylate(PMMA), polyethylene naphthalate (PEN), polycarbonate (PC), polyethersulfone (PES), polyarylate (PAR), polysulfone (PSF), cyclic olefin copolymer(COC), triacetylcellulose(TAC), polyvinyl alcohol(PVA), and polystyrene (PS), and the present disclosure is not limited thereto. For example, the first substrate 201 and the second substrate 202 may be polyimide (PI) substrates. The first substrate 201 may be referred to as a primary PI substrate, and the second substrate 202 may be referred to as a secondary PI substrate. For example, the interlayer insulation film 510 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the exemplary embodiments of the present disclosure are not limited thereto.

Referring to FIG. 5, on the substrate 200, various patterns ACT1, SD1, and GATE1 for forming a transistor, such as a driving transistor DRT, various insulation films 520, 530, 540, 550, 560, 570, and 590, and various metal patterns TM1, GM, ML1, and ML2 may be disposed.

Referring to FIG. 5, a multi-buffer layer 520 may be disposed on the second substrate SUB2. A first active buffer layer 530 may be disposed on the multi-buffer layer 520.

A first metal layer ML1 and a second metal layer ML2 may be disposed on the first active buffer layer 530. The first metal layer ML1 and the second metal layer ML2 may be a light shield layer LS for shielding light.

A second active buffer layer 540 may be disposed on the first metal layer ML1 and the second metal layer ML2. A first active layer ACT1 of the driving transistor DRT may be disposed on the second active buffer layer 540.

A first gate insulation film 550 may be disposed while covering the first active layer ACT1.

A first gate electrode GATE1 of the driving transistor DRT may be disposed on the first gate insulation film 550. In this case, in a position different from the position where the driving transistor DRT is formed, a gate material layer GM, together with the first gate electrode GATE1 of the driving transistor DRT, may be disposed on the first gate insulation film 550.

The first interlayer insulation film 560 may be disposed while covering the first gate electrode GATE1 and the gate material layer GM. A metal pattern TM1 may be disposed on the first interlayer insulation film 560. The metal pattern TM1 may be located in a position different from the position where the driving transistor DRT is formed. The second interlayer insulation film 570 may be disposed while covering the metal pattern TM1 on the first interlayer insulation film 560.

Two first source-drain electrode patterns 580 may be disposed on the second interlayer insulation film 570. One of the two first source-drain electrode patterns 580 is the source node of the driving transistor DRT, and the other is the drain node of the driving transistor DRT. The two first source-drain electrode patterns 580 may be electrically connected with the two opposite sides of the first active layer ACT1 through the contact hole of the second interlayer insulation film 570, the first interlayer insulation film 560, and the first gate insulation film 550.

A portion of the first active layer ACT1 overlapping the first gate electrode GATE1 is a channel area. One of the two first source-drain electrode patterns 580 may be connected to one side of the channel area in the first active layer ACT1, and the other one of the two first source-drain electrode patterns 580 may be connected to the other side of the channel area in the first active layer ACT1.

A passivation layer 590 is disposed while covering the two first source-drain electrode patterns 580. A planarization layer PLN may be disposed on the passivation layer 590. The planarization layer PLN may include a first planarization layer 5101 and a second planarization layer 5102.

The first planarization layer 5101 may be disposed on the passivation layer 590.

A second source-drain electrode pattern 5200 may be disposed on the first planarization layer 5101. The second source-drain electrode pattern 5200 may be connected with one of the two first source-drain electrode patterns 580 (corresponding to the second node N2 of the driving transistor DRT in the subpixel SP of FIG. 3) through the contact hole of the first planarization layer 5101.

The second planarization layer 5102 may be disposed while covering the second source-drain electrode pattern 5200. The configuration from the multi-buffer layer 520 to the second planarization layer 5102 described above may be collectively referred to as a circuit layer CL.

A light emitting element ED may be disposed on the second planarization layer 5102. In the stacked structure of the light emitting element ED, the anode electrode 5300 may be disposed on the second planarization layer 5102. Here, the anode electrode 5300 may have the same configuration as the anode electrode AE illustrated in FIG. 3. The anode electrode 5300 may be electrically connected to the second source-drain electrode pattern 5200 through the contact hole of the second planarization layer 5102.

The bank 5400 may be disposed while covering a portion of the anode electrode 5300. A portion of the bank 5400 corresponding to the light emitting area EA of the subpixel SP may be opened.

A portion of the anode electrode 5300 may be exposed through an opening (open portion) of the bank 5400. A light emitting layer 5500 may be positioned on a side surface of the bank 5400 and the opening (open portion) of the bank 5400. The whole or part of the light emitting layer 5500 may be positioned between adjacent banks 5400. Here, the light emitting layer 5500 may have the same configuration as the light emitting layer EL described above.

In the opening of the bank 5400, the light emitting layer 5500 may contact the anode electrode 5300. An electron injection layer 5600 may be disposed on the light emitting layer 5500. The cathode electrode 5700 may be disposed on the electron injection layer 5600. The cathode electrode 5700 illustrated in FIG. 5 may have the same configuration as the cathode electrode CE illustrated above. However, the electron injection layer 5600 may be a component included in the cathode electrode 5700, but for convenience of description, it is described as a separate component from the cathode electrode 5700 in the disclosure.

The light emitting element ED may be formed by the anode electrode 5300, the light emitting layer 5500, the electron injection layer 5600, and the cathode electrode CE. The light emitting layer 5500 may include an organic film.

A capping layer 5800 may be disposed on the above-described light emitting element ED. The capping layer 5800 may protect the light emitting element ED. The capping layer 5800 may be formed together in the organic deposition process, and the material thereof may be an organic or inorganic material.

An encapsulation layer 5900 may be disposed on the capping layer 5800. The encapsulation layer 5900 may have a single layer structure or a multilayer structure. For example, as illustrated in FIG. 5, the encapsulation layer 5900 may include a first encapsulation layer 5901, a second encapsulation layer 5903, and a third encapsulation layer 5902.

For example, the first encapsulation layer 5901 and the third encapsulation layer 5902 may be inorganic films, and the second encapsulation layer 5903 may be organic films. Among the first encapsulation layer 5901, the second encapsulation layer 5903, and the third encapsulation layer 5902, the second encapsulation layer 5903 may be the thickest and may serve as a planarization layer.

The first encapsulation layer 5901 may be disposed on the capping layer 5800 and may be disposed closest to the capping layer 5800. The first encapsulation layer 5901 may be formed of an inorganic insulating material capable of low temperature deposition. For example, the first encapsulation layer 5901 may be formed of silicon nitride (SiNx), silicon oxide (SiOx), silicon oxynitride (SiON), or aluminum oxide (Al2O3). Since the first encapsulation layer 5901 is deposited in a low-temperature atmosphere, the first encapsulation layer 5901 may prevent or reduce the light emitting layer 5500 including an organic material vulnerable to a high-temperature atmosphere from being damaged during the deposition process.

The second encapsulation layer 5903 may be formed with an area smaller than that of the first encapsulation layer 5901. In this case, the second encapsulation layer 5903 may be formed to expose two opposite ends of the first encapsulation layer 5901. The second encapsulation layer 5903 may serve as a buffer to relieve stress between layers due to bending of the display device 100 and may also serve to enhance planarization performance. For example, the second encapsulation layer 5903 may be an acrylic resin, an epoxy resin, polyimide, polyethylene, silicon oxycarbon (SiOC), or the like, and may be formed of an organic insulating material. For example, the second encapsulation layer 5903 may be formed through an inkjet method.

The third encapsulation layer 5902 may be formed on the substrate 200 on which the second encapsulation layer 5903 is formed to cover the upper surface and the side surface of each of the second encapsulation layer 5903 and the first encapsulation layer 5901. The third encapsulation layer 5902 may minimize or block external moisture or oxygen from penetrating into the first encapsulation layer 5901 and the second encapsulation layer 5903. For example, the third encapsulation layer 5902 is formed of an inorganic insulating material, such as silicon nitride (SiNx), silicon oxide (SiOx), silicon oxynitride (SiON), or aluminum oxide (Al2O3).

Alternatively, the encapsulation layer may include a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer may serve to block the penetration of moisture or oxygen. The first inorganic encapsulation layer, the second inorganic encapsulation layer, and the third inorganic encapsulation layer may be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer may each have a larger thickness than each of the first inorganic encapsulation layer, the second inorganic encapsulation layer, and the third inorganic encapsulation layer in order to adsorb or block particles that may be produced during a process of manufacturing the display device. The first organic encapsulation layer and the second organic encapsulation layer may fill cracks that may be formed in the first inorganic encapsulation layer and the second inorganic encapsulation layer. The first organic encapsulation layer and the second organic encapsulation layer may planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer may planarize an upper portion of the first inorganic encapsulation layer by covering particles on the first inorganic encapsulation layer. For example, the second organic encapsulation layer may planarize an upper portion of the second inorganic encapsulation layer by covering particles on the second inorganic encapsulation layer. The first organic encapsulation layer and the second organic encapsulation layer may be made of an organic material, and for example, epoxy polymer, acrylic polymer, or the like may be used. However, the present disclosure is not limited thereto.

Meanwhile, the encapsulation layer is not limited to three or five layers, for example, n layers alternately stacked between inorganic encapsulation layer and organic encapsulation layer (where n is an integer greater than 3) may be included.

Next, a stacked structure for the optical area OA is described with reference to FIG. 5.

Referring to FIG. 5, the emission area EA in the optical area OA may have the same stacked structure as the stacked structure of the normal area NA. Therefore, the stacked structure of the transmissive area TA in the first optical area OA1 is described below in detail.

The cathode electrode CE and the electron injection layer 5600 are disposed in the emission area EA included in the optical area OA and in the emission area EA included the normal area NA, but the cathode electrode CE and the electron injection layer 5600 may not be disposed in the transmissive area TA in the optical area OA. In other words, the transmissive area TA in the optical area OA may correspond to the opening of the cathode electrode CE.

Further, the light shield layer LS including at least one of the first metal layer ML1 and the second metal layer ML2 is disposed in the emission area EA included in the optical area OA and the normal area NA, but the light shield layer LS may not be disposed in the transmissive area TA in the optical area OA. In other words, the transmissive area TA in the optical area OA may correspond to the opening of the light shield layer LS.

The substrate 200 and various insulation films 520, 530, 540, 550, 560, 570, 590, 5100 (5101, 5102), 5400, 5900 (5901, 5902, 5903) disposed in the emission area EA included in the normal area NA and the optical area OA may be equally disposed in the transmissive area TA in the optical area OA.

However, in the emission area EA included in the normal area NA and the optical area OA, a material layer (e.g., a metal material layer, a semiconductor layer, etc.) having electrical properties other than the insulating material may not be disposed in the transmissive area TA in the optical area OA.

For example, referring to FIG. 5, the metal material layers ML1, ML2, GATE1, GM, TM1, SD1, and SD2 related to the transistor and the semiconductor layer may not be disposed in the transmissive area TA in the optical area OA.

Further, referring to FIG. 5, the anode electrode 5300 and the cathode electrode CE included in the light emitting element ED may not be disposed in the transmissive area TA in the optical area OA. However, the emission layer 5500 may or may not be disposed in the transmissive area TA in the optical area OA.

Therefore, light transmittance of the transmissive area TA in the optical area OA may be provided by not disposing a material layer (e.g., a metal material layer, a semiconductor layer, etc.) having electrical characteristics in the optical area OA. Therefore, the second optical electronic device 11 may receive light transmitted through the transmissive area TA and perform the corresponding function (e.g., sensing the approach of an object or human body, detecting external illuminance, etc.).

Meanwhile, as the cathode electrode CE and the electron injection layer 5600 are not disposed in the transmissive area TA in the optical area OA, as described above with reference to FIG. 4, the sheet resistance may increase as the area of the cathode electrode 5700 in the optical area OA decreases. As the sheet resistance of the cathode electrode 5700 of the optical area OA increases, a difference in luminance may occur between the optical area OA and the boundary area BT that is a peripheral portion of the optical area OA.

In an exemplary embodiment of the disclosure, the above-described issues may be addressed by disposing a resistance enhancement structure 600 in the optical area OA.

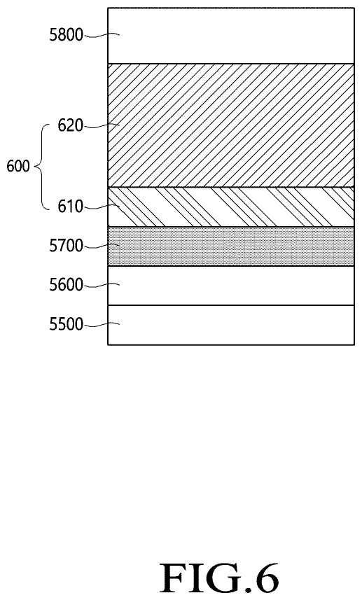

FIG. 6 is a schematic view illustrating a resistance enhancement structure 600 according to exemplary embodiments of the disclosure.

The resistance enhancement structure 600 may include a conductive material layer 610 and a transparent electrode 620. The resistance enhancement structure 600 may be disposed on the cathode electrode 5700.

Here, the cathode electrode 5700 is a thin film cathode electrode 5700 disposed in the optical area OA, and may have a smaller thickness than the cathode electrode 5700 disposed in the normal area NA. For example, the thickness of the thin film cathode electrode 5700 disposed in the optical area OA may be ⅕ to ⅓ of the thickness of the cathode electrode 5700 disposed in the normal area NA. For example, the thickness of the thin film cathode electrode 5700 disposed in the optical area OA may be as thin as a quarter of the cathode electrode 5700 disposed in the normal area NA. This is an example for description, and the thickness of the thin film cathode electrode 5700 is not limited thereto.

The thickness of the conductive material layer 610 may be identical or similar to the thickness of the thin film cathode electrode 5700. The thickness of the transparent electrode 620 may be larger than a thickness of the conductive material layer 610. For example, the thickness of the transparent electrode 620 may be 5 to 20 times of the thickness of the conductive material layer 610. For example, the thickness of the transparent electrode 620 may be about 10 times larger than the thickness of the conductive material layer 610. However, the thicknesses of the conductive material layer 610 and the transparent electrode 620 are not limited thereto.

In other words, the electron injection layer 5600 may be disposed on the light emitting layer 5500, and the thin film cathode electrode 5700 may be disposed on the electron injection layer 5600. A resistance enhancement structure 600 may be disposed on the thin film cathode electrode 5700, and a capping layer 5800 may be disposed on the resistance enhancement structure 600.

The thin film cathode electrode 5700 and the resistance enhancement structure 600 may be disposed in the optical area OA of the display panel 110.

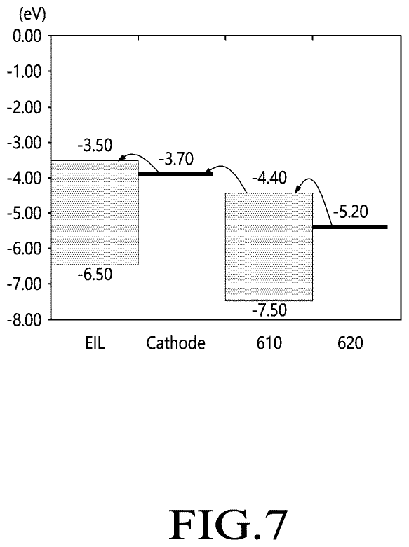

FIG. 7 is the graph illustrating the work function and the lowest unoccupied molecular orbital value of components of the resistance enhancement structure 600 according to exemplary embodiments of the disclosure.

The conductive material layer 610 may include an organic material or an inorganic material and may have conductivity. For example, the conductive material layer 610 may be a metal inorganic compound such as BaF2, LiF, NaCl, CsF, Li2O, Cu2O, Fe2O3, WO3, and BaO. Alternatively, it may be an organic compound, such as at least one of HAT-CN(dipyrazino[2,3-f: 2′,3′-h]quinoxaline-2,3,6,7,10.11-hexacarbonitrile), CuPc(phthalocyanine), and NPD(N,N′-bis(naphthalene-1-yl)-N,N′-bis(phenyl)-2,2′-dimethylbenzidine).

The transparent electrode 620 is a transparent conductive material and may include any one of indium tin oxide (ITO), indium zinc oxide (IZO), and indium gallium zinc oxide (IGZO).

In the graph illustrated in FIG. 7, the conductive material layer 610 is assumed to be an organic material. As described above, the conductive material layer 610 may be an inorganic material, unlike the one illustrated in the graph.

Further, the graph shown in FIG. 7 depicts the electron injection layer EIL, assuming that it is an organic material. However, the constituent material of the electron injection layer 5600 is not limited thereto and may be an inorganic material. When the electron injection layer EIL is an organic material, it may include a material such as TPBi, Bphen, Alq3, etc. Alternatively, when the electron injection layer 5600 is an inorganic material, it may include a material such as LiF, Ca, or Al2O3.

The graph illustrated in FIG. 7 represents the lowest unoccupied molecular orbital (LUMO) values of respective organic materials and the work function values of respective inorganic materials for the electron injection layer 5600, the cathode electrode 5700 disposed adjacent to the electron injection layer 5600, the conductive material layer 610 disposed adjacent to the cathode electrode 5700, and the transparent electrode 620 disposed adjacent to the conductive material layer 610.

For example, the work function of the transparent electrode 620 may be −5.2 eV. The lowest unoccupied molecular orbital value of the conductive material layer 610 disposed adjacent to the lower surface of the transparent electrode 620 may be −4.4 eV. The work function of the cathode electrode 5700 disposed to be adjacent to the lower surface of the conductive material layer 610 may be −3.7 eV. The lowest unoccupied molecular orbital value of the electron injection layer 5600 disposed adjacent to the lower surface of the cathode electrode 5700 may be −3.5 eV.

In other words, the lowest unoccupied molecular orbital value of the electron injection layer 5600 may be higher than the work function of the cathode electrode 5700. The work function of the cathode electrode 5700 may be higher than the lowest unoccupied molecular orbital value of the conductive material layer 610. The lowest unoccupied molecular orbital value of the conductive material layer 610 may be higher than the work function of the transparent electrode 620.

However, when the electron injection layer 5600 includes an inorganic material, the work function of the electron injection layer 5600 may be a value higher than the work function of the cathode electrode 5700. Further, when the conductive material layer 610 includes an inorganic material, the work function of the conductive material layer 610 may be lower than that of the cathode 5700 and higher than that of the transparent electrode 620.

Thus, by disposing the conductive material layer 610 and the transparent electrode 620, which are the resistance enhancement structure 600, in addition to the existing structure of the electron injection layer 5600 and the cathode electrode 5700, the flow of electrons from the transparent electrode 620 to the conductive material layer 610, the cathode electrode 5700, and the electron injection layer 5600 may be facilitated. This may reduce the increase in conductance, i.e., resistance, of the cathode electrode 5700 in the optical area OA where the resistance enhancement structure 600 is positioned.

The sheet resistance of the cathode electrode 5700, which increases as the cathode hole CH is formed in the cathode electrode 5700 in the optical area OA, may be offset by disposing the resistance enhancement structure 600 on the cathode electrode 5700.

As a result, it may reduce the luminance deviation between pixels disposed in the optical area OA and pixels disposed in the boundary area BT, thereby allowing the display panel 110 to output an image of uniform quality.

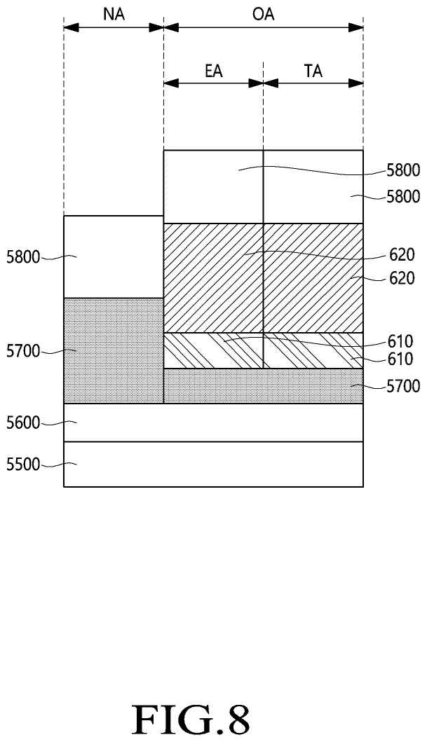

FIG. 8 is a view schematically illustrating a structure in which a resistance enhancement structure 600 is disposed when a cathode electrode 5700 is disposed in a transmissive area TA in a display area DA according to exemplary embodiments of the disclosure.

Referring to FIG. 8, the display area DA may include an optical area OA and a normal area NA. Since the configuration of the boundary area BT is the same as that of the normal area NA, the illustration thereof is omitted in FIG. 8.

The optical area OA may include an emission area EA and a transmissive area TA. The emission area EA may be an area where the light emitting element ED is disposed to directly emit light. The transmissive area TA may be an area through which light outside the display device 100 enters to allow the optical electronic device 11 positioned behind the display panel 110 (on the side opposite to the viewing surface) to receive light.

As described in connection with FIG. 5, in the normal area NA, an electron injection layer 5600 may be disposed on the light emitting layer 5500. The cathode electrode 5700 may be disposed on the electron injection layer 5600. A capping layer 5800 may be disposed on the cathode electrode 5700.

The light emitting layer 5500 may be disposed in the emission area EA and the transmissive area TA of the optical area OA. However, the light emitting layer 5500 may or may not be disposed in the transmissive area TA. The electron injection layer 5600 may be disposed on the light emitting layer 5500. When the light emitting layer 5500 is not disposed in the transmissive area TA, the electron injection layer 5600 may be directly disposed. The cathode electrode 5700 may be disposed on the electron injection layer 5600. In other words, referring to FIG. 8, the cathode hole CH may not be formed in the transmissive area TA of the optical area OA, and the cathode electrode 5700 may be disposed.

The cathode electrode 5700 disposed in the optical area OA may be a thin film cathode electrode 5700 having a thickness smaller than that of the cathode electrode 5700 disposed in the normal area NA. For example, the thickness of the cathode electrode 5700 disposed in the optical area OA may be about ⅕ to ⅓ of the thickness of the cathode electrode 5700 disposed in the normal area NA. For example, the thickness of the cathode electrode 5700 disposed in the optical area OA may be about a quarter of the thickness of the cathode electrode 5700 disposed in the normal area NA.

A conductive material layer 610 may be disposed on the cathode electrode 5700 of the optical area OA. As described above with reference to FIG. 7, the conductive material layer 610 may include an organic material or an inorganic material. The transparent electrode 620 may be disposed on the conductive material layer 610. The transparent electrode 620 may include a transparent conductive material as described above with reference to FIG. 7. The capping layer 5800 may be disposed on the transparent electrode 620.

For example, the conductive material layer 610 may be a metal inorganic compound such as BaF2, LiF, NaCl, CsF, Li2O, Cu2O, Fe2O3, WO3, and BaO. Alternatively, it may be an organic compound, such as at least one of HAT-CN(dipyrazino[2,3-f: 2′,3′-h]quinoxaline-2,3,6,7,10.11-hexacarbonitrile), CuPc(phthalocyanine), and NPD(N,N′-bis(naphthalene-1-yl)-N,N′-bis(phenyl)-2,2′-dimethylbenzidine).

The transparent electrode 620 is a transparent conductive material and may include any one of indium tin oxide (ITO), indium zinc oxide (IZO), and indium gallium zinc oxide (IGZO).

By the optical area OA structure illustrated in FIG. 8, the cathode electrode 5700 may be thinly disposed, and the conductive material layer 610 and the transparent electrode 620 may be positioned without forming the cathode hole CH in the transmissive area TA, preventing or reducing an increase in sheet resistance while maintaining the transmittance of the transmissive area TA.

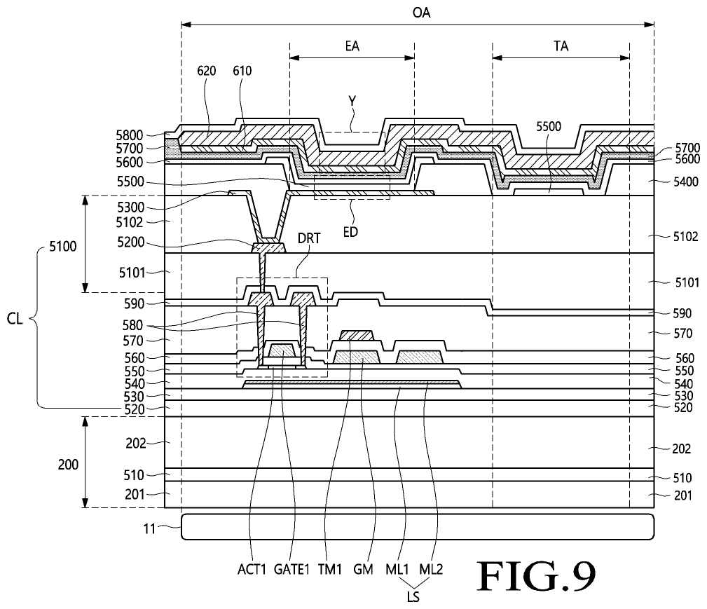

FIG. 9 is a cross-sectional view illustrating an optical area in which a resistance enhancement structure 600 is disposed according to the exemplary embodiment of FIG. 8.

Referring to FIG. 9, the configuration of the optical area OA of the display panel 110 may be identical to that illustrated in FIG. 5 in term of the configuration of the optical electronic device 11, the substrate 200, and the circuit layer CL.

Referring to FIG. 9, the thickness of the cathode electrode 5700 disposed in the optical area OA may be a thickness of a thin film cathode electrode 5700 that is smaller than the thickness of the cathode electrode 5700 disposed in the normal area NA. For example, the thickness of the cathode electrode 5700 disposed in the optical area OA may be about ⅕ to ⅓ the thickness of the cathode electrode 5700 disposed in the normal area NA. For example, the thickness of the cathode electrode 5700 disposed in the optical area OA may be about a quarter of the thickness of the cathode electrode 5700 disposed in the normal area NA. Further, the electron injection layer 5600 and the thin film cathode electrode 5700 may also be disposed in the transmissive area TA of the optical area OA.

Referring to FIGS. 9 and 6, a resistance enhancement structure 600 may be disposed between the cathode electrode 5700 and the capping layer of the optical area OA. The resistance enhancement structure 600 may include a conductive material layer 610 and a transparent electrode 620. The conductive material layer 610 may be disposed on the cathode electrode 5700, and the transparent electrode 620 may be disposed on the conductive material layer 610.

The electron injection layer 5600, the thin film cathode electrode 5700, and the resistance enhancement structure 600 may be disposed over the entire optical area OA. Therefore, even when the thickness of the cathode electrode 5700 in the optical area OA is smaller than that of the cathode electrode 5700 in the normal area NA, the sheet resistance of the cathode electrode 5700 in the optical area OA may not be increased.

Further, since the thickness of the cathode electrode 5700 disposed in the optical area OA is small, transmittance may be enhanced. For example, the transmittance of light emitted from the light emitting element ED in the emission area EA may be enhanced. Further, it is possible to enhance the transmittance of light received from the outside of the display panel 110 to the optical electronic device 11 through the transmissive area TA.

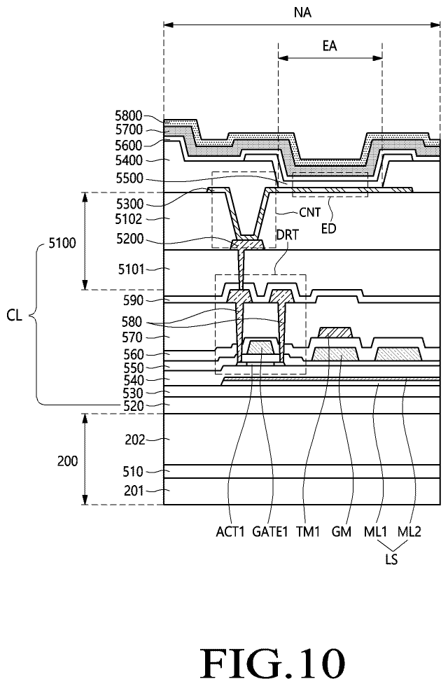

FIG. 10 is a cross-sectional view illustrating a normal area NA adjacent to the optical area OA shown in the cross-sectional view of FIG. 9 according to one embodiment.

The normal area NA illustrated in FIG. 10 may be an area adjacent to the optical area OA illustrated in FIG. 9.

Referring to FIGS. 5 and 10, the configuration of the normal area NA illustrated in FIG. 10 may be identical to the configuration of the normal area NA illustrated in FIG. 5. In other words, the resistance enhancement structure 600 including the conductive material layer 610 and the transparent electrode 620 may not be disposed in the normal area NA.

Referring to FIGS. 9 and 10, the resistance enhancement structure 600 may be disposed in the optical area OA, but may not be disposed in the normal area NA. Further, the thickness of the cathode electrode 5700 disposed in the normal area NA may be larger than the thickness of the cathode electrode 5700 disposed in the optical area OA. For example, the thickness of the cathode electrode 5700 disposed in the normal area NA may be 3 to 5 times of the thickness of the cathode electrode 5700 disposed in the optical area OA. For example, the thickness of the cathode electrode 5700 disposed in the normal area NA may be four times larger than the thickness of the cathode electrode 5700 disposed in the optical area OA.

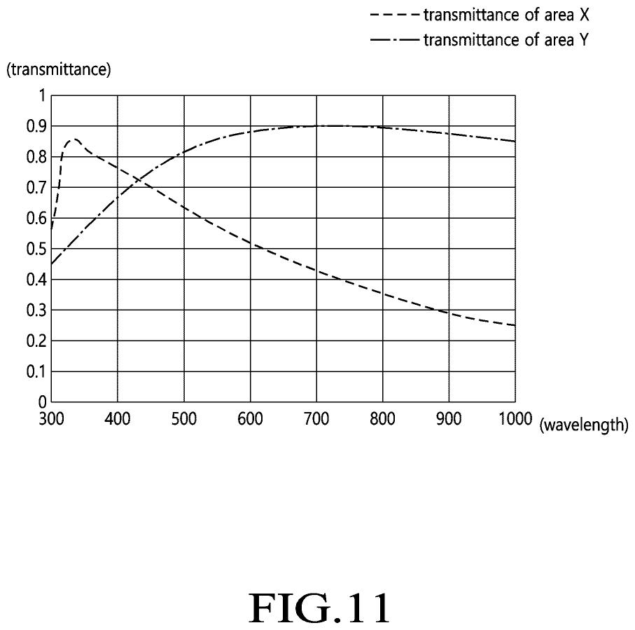

FIG. 11 is a graph comparing the transmittance between an emission area EA where a resistance enhancement structure 600 is disposed and an emission area EA where a resistance enhancement structure is not disposed according to exemplary embodiments of the disclosure.

The x-axis of FIG. 11 is the wavelength axis and may indicate the wavelength length in nm. The y-axis may be a transmittance.

Referring to FIG. 5, the X area may be the emission area EA in the optical areas OA where the resistance enhancement structure 600 is not disposed. Specifically, the X area may be an area including the electron injection layer 5600, the cathode electrode 5700, and the capping layer 5800 in the light emitting layer 5500 in the optical area OA where the resistance enhancement structure 600 is not disposed.

Referring to FIG. 9, the Y area may be an emission area EA in the optical area OA where the resistance enhancement structure 600 is disposed. Specifically, the Y area may be an area including the electron injection layer 5600, the cathode electrode 5700, the conductive material layer 610, the transparent electrode 620, and the capping layer in the emission layer 5500 in the optical area OA where the resistance enhancement structure 600 is disposed.

In the X area where the resistance enhancement structure 600 is not disposed, the transmittance of light up to about 330 nm band may rise to about 0.85, and the transmittance of light from 330 nm band may decrease. In particular, in the 700 nm band, which is a wavelength band where light is recognized as red, the transmittance may not reach 0.5. The term ‘light’ as used herein may mean an electromagnetic wave.

In the Y area where the resistance enhancement structure 600 is disposed, the transmittance of light up to about 700 nm band may increase, and the transmittance of light over about 500 nm band may be 0.8 or more.

Referring to FIG. 11, the transmittance of light in a band of about 430 nm or more may be higher in the Y area where the resistance enhancement structure 600 is disposed than in the X area where the resistance enhancement structure 600 is not disposed.

In other words, the resistance enhancement structure 600 may not only reduce the sheet resistance of the cathode electrode 5700 in the optical area OA, but also enhance light transmittance.

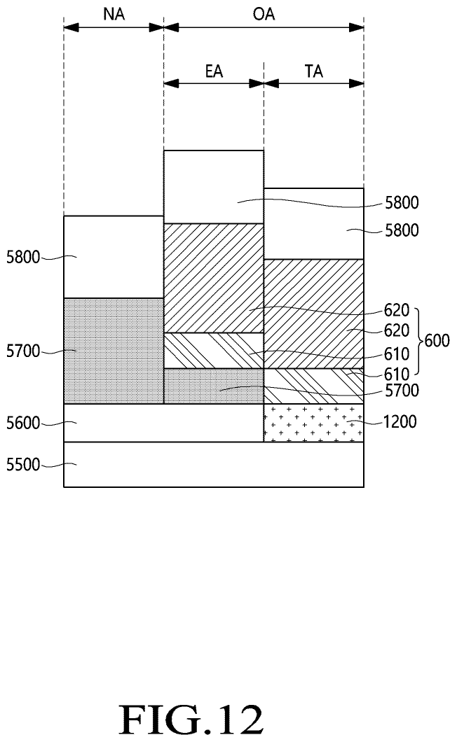

FIG. 12 is a view schematically illustrating a structure in which a resistance enhancement structure 600 is disposed when a cathode electrode 5700 is not disposed in a transmissive area TA in a display area DA according to exemplary embodiments of the disclosure.

Referring to FIGS. 12 and 8, the emission area EA of the optical area OA and the normal area NA illustrated in FIG. 12 may be the same as the emission area EA of the optical area OA and the normal area NA illustrated in FIG. 8.

In other words, referring to FIG. 12, a light emitting layer 5500 may be disposed in the normal area NA. An electron injection layer 5600 may be disposed on the light emitting layer 5500. The cathode electrode 5700 may be disposed on the electron injection layer 5600. A capping layer 5800 may be disposed on the cathode electrode 5700.

The light emitting layer 5500 may be disposed in the emission area EA of the optical area OA. The electron injection layer 5600 may be disposed on the light emitting layer 5500. The cathode electrode 5700 may be disposed on the electron injection layer 5600.

Like the thin film cathode electrode 5700 disposed in the optical area OA of FIG. 8, the cathode electrode 5700 disposed in the emission area EA of the optical area OA with reference to FIG. 12 may be a thin film cathode electrode 5700 having a thickness smaller than that of the cathode electrode 5700 disposed in the normal area NA.

A conductive material layer 610 may be disposed on the cathode electrode 5700 of the emission area EA of the optical area OA. As described above with reference to FIG. 7, the conductive material layer 610 may include an organic material or an inorganic material. The transparent electrode 620 may be disposed on the conductive material layer 610. The transparent electrode 620 may include a transparent conductive material as described above with reference to FIG. 7. The capping layer 5800 may be disposed on the transparent electrode 620.

For example, the conductive material layer 610 may be a metal inorganic compound such as BaF2, LiF, NaCl, CsF, Li2O, Cu2O, Fe2O3, WO3, and BaO. Alternatively, it may be an organic compound, such as at least one of HAT-CN(dipyrazino[2,3-f: 2′,3′-h]quinoxaline-2,3,6,7, 10.11-hexacarbonitrile), CuPc(phthalocyanine), and NPD(N,N′-bis(naphthalene-1-yl)-N,N′-bis(phenyl)-2,2′-dimethylbenzidine).

The transparent electrode 620 is a transparent conductive material and may include any one of indium tin oxide (ITO), indium zinc oxide (IZO), and indium gallium zinc oxide (IGZO).

Meanwhile, referring to FIG. 12, the electron injection layer 5600 and the cathode electrode 5700 may not be disposed in the transmissive area TA of the optical area OA.

Specifically, the light emitting layer 5500 may be disposed in the transmissive area TA of the optical area OA. However, the light emitting layer 5500 may or may not be disposed in the transmissive area TA. The patterning layer 1200 may be disposed on the light emitting layer 5500 of the transmissive area TA. When the light emitting layer 5500 is not disposed, the patterning layer 1200 may be directly disposed.

The patterning layer 1200 may be formed of a carbon organic material such as 3-(Biphenyl-4-yl)-5-(4-tert-butylphenyl)-4-phenyl-4H-1,2,4-triazole(TAZ), but the disclosure is not limited thereto. Since the patterning layer 1200 has a low-adhesion characteristic with low surface energy of the material itself or high interfacial energy between the metal and the MPL, the probability of desorption of metal on the MPL surface during metal deposition is significantly increased, and metal nucleation does not occur. In other words, the patterning layer 1200 may serve to prevent the cathode 5700 from being formed in the transmissive area TA. Thus, a cathode hole CH may be formed in the transmissive area TA of the optical area OA.

A conductive material layer 610 may be disposed on the patterning layer 1200 of the transmissive area TA. As described above with reference to FIG. 7, the conductive material layer 610 may include an organic material or an inorganic material. The transparent electrode 620 may be disposed on the conductive material layer 610. The transparent electrode 620 may include a transparent conductive material as described above with reference to FIG. 7. The capping layer 5800 may be disposed on the transparent electrode 620.

For example, the conductive material layer 610 may be a metal inorganic compound such as BaF2, LiF, NaCl, CsF, Li2O, Cu2O, Fe2O3, WO3, and BaO. Alternatively, it may be an organic compound, such as at least one of HAT-CN(dipyrazino[2,3-f: 2′,3′-h]quinoxaline-2,3,6,7,10.11-hexacarbonitrile), CuPc(phthalocyanine), and NPD(N,N′-bis(naphthalene-1-yl)-N,N′-bis(phenyl)-2,2′-dimethylbenzidine).

The transparent electrode 620 is a transparent conductive material and may include any one of indium tin oxide (ITO), indium zinc oxide (IZO), and indium gallium zinc oxide (IGZO).

Referring to FIG. 12, by excluding the cathode 5700 from the transmissive area TA in the optical area OA, the transmittance of light received by the optical electronic device 11, located behind the optical area OA of the display panel 110 (opposite the viewing surface), may be enhanced.

Further, as the resistance enhancement structure 600 is disposed in the optical area OA, it is possible to offset the effect of increasing sheet resistance as the thickness of the cathode electrode 5700 in the optical area OA becomes thinner.

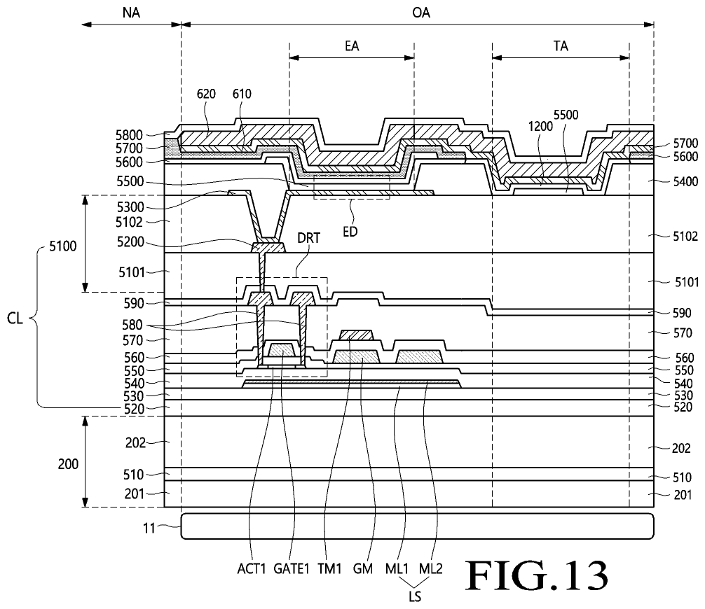

FIG. 13 is a cross-sectional view illustrating an optical area OA in which a resistance enhancement structure 600 is disposed according to the exemplary embodiment of FIG. 12.

Referring to FIG. 13, the optical area OA of the display panel 110 may have the same configuration as the configuration of the optical area OA illustrated in FIG. 9 except for the cathode electrode 5700 and the electron injection layer 5600.

Specifically, referring to FIG. 13, the electron injection layer 5600 may be disposed on the light emitting layer 5500 in an area other than the transmissive area TA in the optical area OA. A cathode 5700 may be disposed on the electron injection layer 5600. The cathode electrode 5700, disposed in the area other than the transmissive area TA in the optical area OA, may be a thin film cathode electrode with a thickness equal to about ¼ of a thickness the cathode electrode 5700 positioned in the normal area NA. The thin film cathode electrode 5700 and the electron injection layer 5600 may not be disposed in the transmissive area TA.

Meanwhile, a patterning layer 1200 may be disposed on the light emitting layer 5500 of the transmissive area TA in the optical area OA. However, the light emitting layer 5500 may not be disposed in the transmissive area TA, and the patterning layer 1200 may be disposed. The electron injection layer 5600 and the cathode electrode 5700 may not be disposed on the patterning layer 1200 disposed in the transmissive area TA, but the conductive material layer 610 may be disposed. The transparent electrode 620 may be disposed on the conductive material layer 610.

Meanwhile, the configuration of the normal area NA adjacent to the optical area OA illustrated in FIG. 13 may be identical to the configuration of the normal area NA illustrated in FIG. 10. In other words, the resistance enhancement structure 600 including the conductive material layer 610 and the transparent electrode 620 may not be disposed in the normal area NA.

Referring to FIG. 13, by excluding the cathode 5700 from the transmissive area TA in the optical area OA as described in connection with FIG. 12, the transmittance of light received by the optical electronic device 11, located behind the optical area OA of the display panel 110 (opposite the viewing surface), may be enhanced.

Further, as the resistance enhancement structure 600 is disposed in the optical area OA, it is possible to offset the effect of increasing sheet resistance as the thickness of the cathode electrode 5700 in the optical area OA becomes thinner.

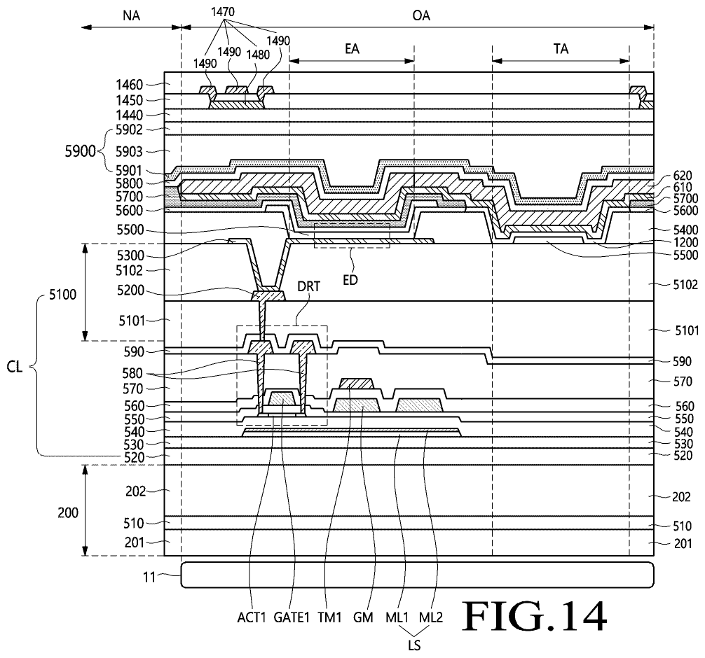

FIG. 14 is a cross-sectional view illustrating an optical area in which a resistance enhancement structure and a touch sensor are disposed according to exemplary embodiments of the disclosure.

The configuration of the optical area OA illustrated in FIG. 14 may be identical to that illustrated in FIG. 13 in the term of the configuration of the optical electronic device 11, the substrate 200, the circuit layer CL, and the resistance enhancement structure 600.

Referring to FIG. 14, an encapsulation layer 5900 may be disposed on the capping layer 5800 of the optical area OA. The touch sensor 1470 may be disposed on the encapsulation layer 5900. The touch sensor structure is described below in detail.

A touch buffer film 1440 may be disposed on the encapsulation layer 5900. The touch sensor 1470 may be disposed on the touch buffer film 1440.

The touch sensor 1470 may include touch sensor metals 1490 and a bridge metal 1480 positioned in different layers.

A touch interlayer insulation film 510 may be disposed between the touch sensor metals 1490 and the bridge metal 1480.

For example, a first touch sensor metal 1490, a second touch sensor metal 1490, and a third touch sensor metal 1490 where the touch sensor metals 1490 are disposed adjacent to each other may be included. When the third touch sensor metal 1490 is present between the first touch sensor metal 1490 and the second touch sensor metal 1490, and the first touch sensor metal 1490 and the second touch sensor metal 1490 need to be electrically connected to each other, the first touch sensor metal 1490 and the second touch sensor metal 1490 may be electrically connected to each other through the bridge metal 1480 in the different layer. The bridge metal 1480 may be insulated from the third touch sensor metal 1490 by the touch interlayer insulation film 510.

When the touch sensor 1470 is formed on the display panel 110, a chemical liquid (such as a developer or an etchant) used in the process or moisture from the outside may be generated. As the touch sensor 1470 is disposed on the touch buffer film 1440, a manufacturing process reagent solution or moisture of the touch sensor 1470 may be prevented from penetrating into the light emitting layer 5500 including an organic material. Thus, the touch buffer film 1440 may prevent damage to the light emitting layer 5500 vulnerable to chemicals or moisture.

The touch buffer film 1440 is formed of an organic insulating material that may be formed at a low temperature below a predetermined temperature (e.g., 100° C.) and has a low dielectric constant of 1 to 3 to prevent damage to the light emitting layer 5500 including an organic material vulnerable to high temperatures. For example, the touch buffer film 1440 may be formed of an acrylic-based, epoxy-based, or siloxane-based material. As the display device 100 is bent, the encapsulation layer 5900 may be damaged, and the touch sensor metal positioned on the touch buffer film 1440 may be broken. Even when the display device 100 is bent, the touch buffer film 1440 formed of an organic insulating material to have planarization performance may prevent damage to the encapsulation layer 5900 and/or breakage of the metals 1480 and 1490 constituting the touch sensor TS.

The protective layer 1460 may be disposed while covering the touch sensor 1470. The protective layer 1460 may be an organic insulation layer.

The cover window may be disposed to cover the protective layer 1460. However, the cover window is omitted from the illustration in the drawings. The cover window may serve to protect the display panel 110 from being broken by an external impact.

Referring to FIG. 14, the touch sensor 1470 may not overlap the emission area EA and the transmissive area TA of the optical area OA.

Meanwhile, the configuration of the normal area NA adjacent to the optical area OA illustrated in FIG. 14 is identical to that of the normal area NA illustrated in FIG. 10, and the touch buffer film 1440, the touch sensor metal 1490, the bridge metal 1480, and the touch interlayer insulation film 510 described above may be disposed on the configuration of the normal area NA illustrated in FIG. 10.

Further, the resistance enhancement structure 600 including the conductive material layer 610 and the transparent electrode 620 may not be disposed in the normal area NA.

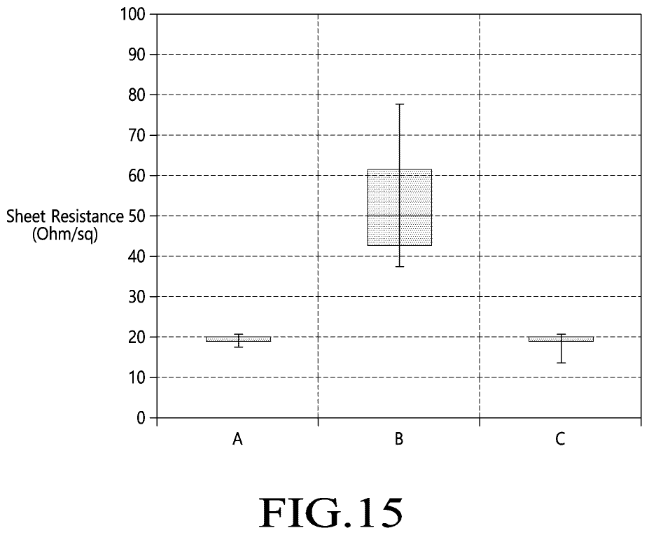

FIG. 15 is a graph illustrating a resistance enhancement effect according to exemplary embodiments of the disclosure.

Item A in the graph may represent the sheet resistance of the cathode electrode 5700 in the normal area NA. Item B in the graph may represent the sheet resistance of the cathode electrode 5700 in the optical area OA where the resistance enhancement structure 600 is not disposed. In other words, item B in the graph may be the sheet resistance of the cathode electrode 5700 of the optical area OA illustrated in FIG. 5. Item C in the graph may represent the sheet resistance of the cathode electrode 5700 in the optical area OA where the resistance enhancement structure 600 is disposed. In other words, item C in the graph may be the sheet resistance of the cathode electrode 5700 of the optical area OA illustrated in FIGS. 9, 13, and 14.

Referring to item A of FIG. 15, the maximum sheet resistance of the cathode electrode 5700 in the normal area NA may be about 20 ohm/sq.

Referring to item B of FIG. 15, the maximum value of the sheet resistance of the cathode

electrode 5700 in the optical area OA where the resistance enhancement structure 600 is not disposed may be about 78 ohm/sq. Since the cathode hole CH is formed in the cathode electrode 5700 to receive light by the optical electronic device 11 in the optical area OA, the area of the cathode electrode 5700 may be decreased, and thus the sheet resistance may increase as illustrated in item B in the graph of FIG. 15. Accordingly, the sheet resistance of the cathode electrode 5700 of the boundary area BT adjacent to the optical area may be relatively decreased. Therefore, a potential issue may arise where the luminance of pixels situated in each of the optical area OA and the boundary area BT adjacent to the optical area OA becomes non-uniform relative to one another.

Referring to the item C of FIG. 15, the maximum sheet resistance of the cathode electrode 5700 in the optical area OA where the resistance enhancement structure 600 is disposed may be about 20 ohm/sq, which may be similar to the maximum sheet resistance of the cathode electrode 5700 in the normal area NA. Accordingly, a deviation in sheet resistance of the cathode electrode 5700 between the optical area OA and the boundary area BT adjacent to the optical area OA may be decreased. Accordingly, a problem where a luminance deviation occurs between pixels disposed in each of the optical area OA and the boundary area BT may be solved.

Exemplary embodiments of the disclosure described above are briefly described below.

A display device may comprise a substrate including a normal area including a plurality of first emission areas and an optical area including a plurality of second emission areas and a plurality of transmissive areas, a circuit layer disposed on the substrate, a pixel electrode disposed on the circuit layer, a light emitting layer disposed on the pixel electrode, a common electrode disposed on the light emitting layer, a conductive material layer disposed on the common electrode, and a transparent electrode disposed on the conductive material layer.

In the optical area, the common electrode may not have a plurality of holes overlapping the plurality of transmissive areas.

In the optical area, the common electrode may have a plurality of holes overlapping the plurality of transmissive areas.

The display device may further comprise a patterning layer disposed on the substrate and overlapping the plurality of transmissive areas. The patterning layer may overlap the plurality of holes. The conductive material layer may be positioned on the patterning layer.

The conductive material layer and the transparent electrode may not be disposed in the normal area.

The display device may further comprise an electron injection layer disposed under the conductive material layer.

The electron injection layer may not overlap the plurality of transmissive areas.

The common electrode may include a first common electrode portion disposed in the normal area and a second common electrode portion disposed in the optical area. A thickness of the first common electrode portion may be larger than a thickness of the second common electrode portion.

The conductive material layer may include an organic material or an inorganic material.

The transparent electrode may include an inorganic material.

A work function value of the transparent electrode may be lower than a work function value of the common electrode.

A lowest unoccupied molecular orbital value or work function value of the conductive material layer may be lower than a work function value of the common electrode and higher than a work function value of the transparent electrode.

A thickness of the transparent electrode may be larger than a thickness of each of the conductive material layer and the common electrode.

The display device may further comprise an encapsulation layer disposed on the transparent electrode, and a touch sensor disposed on the encapsulation layer. The touch sensor may not overlap the transmissive area and the emission area.

A display device may comprise a substrate, a circuit layer disposed on the substrate, a pixel electrode disposed on the circuit layer, a light emitting layer disposed on the pixel electrode, a common electrode disposed on the light emitting layer, an encapsulation layer disposed on the common electrode, a metal layer disposed between the common electrode and the encapsulation layer, and an organic layer or an inorganic layer disposed between the common electrode and the metal layer.

The substrate may include a normal area including a plurality of first emission areas and an optical area including a plurality of second emission areas and a plurality of transmissive areas.

The metal layer may be disposed in the optical area, out of the normal area and the optical area. The metal layer may be a transparent electrode.

The substrate may include a normal area including a plurality of first emission areas and an optical area including a plurality of second emission areas and a plurality of transmissive areas. The organic layer or the inorganic layer may be disposed in the optical area, out of the normal area and the optical area.

The organic layer or the inorganic layer may have conductivity.

A display device may comprise a substrate including a normal area including a plurality of first emission areas and an optical area including a plurality of second emission areas and a plurality of transmissive areas; a first electrode disposed over the substrate; a conductive material layer disposed on the first electrode; and a transparent electrode disposed on the conductive material layer.

The conductive material layer and the transparent electrode are disposed in the optical area and not disposed in the normal area.

The conductive material layer includes an organic material or an inorganic material having conductivity.

The transparent electrode includes at least one of indium tin oxide (ITO), indium zinc oxide (IZO), and indium gallium zinc oxide (IGZO).

A thickness of the first electrode in the normal area is greater than a thickness of the first electrode in optical area.

The thickness of the first electrode in the normal area is 4 times larger than the thickness of the first electrode in optical area.

A thickness of the conductive material layer is equal to the thickness of the first electrode in optical area.

A thickness of the transparent electrode is greater the thickness of the conductive material layer.

The first electrode is a common electrode.

The above description has been presented to enable any person skilled in the art to make and use the technical idea of the disclosure, and has been provided in the context of a particular application and its requirements. Various modifications, additions and substitutions to the described exemplary embodiments will be readily apparent to those skilled in the art, and the general principles defined herein may be applied to other exemplary embodiments and applications without departing from the spirit and scope of the disclosure. The above description and the accompanying drawings provide an example of the technical idea of the disclosure for illustrative purposes only. That is, the disclosed exemplary embodiments are intended to illustrate the scope of the technical idea of the disclosure.

What is claimed:

1. A display device, comprising:
a substrate including a normal area including a plurality of first emission areas and an optical area including a plurality of second emission areas and a plurality of transmissive areas;
a circuit layer on the substrate;
a pixel electrode on the circuit layer;
a light emitting layer on the pixel electrode;
a common electrode on the light emitting layer;
a conductive material layer on the common electrode; and
a transparent electrode on the conductive material layer.

2. The display device of claim 1, wherein in the optical area, the common electrode lacks a plurality of holes overlapping the plurality of transmissive areas.

3. The display device of claim 1, wherein in the optical area, the common electrode has a plurality of holes that overlap the plurality of transmissive areas.

4. The display device of claim 3, further comprising:
a patterning layer on the substrate, the patterning layer overlapping the plurality of transmissive areas,
wherein the patterning layer overlaps the plurality of holes, and
wherein the conductive material layer is on the patterning layer.

5. The display device of claim 2, wherein the conductive material layer and the transparent electrode are not in the normal area.

6. The display device of claim 1, further comprising:
an electron injection layer under the conductive material layer.

7. The display device of claim 6, wherein the electron injection layer is non-overlapping with the plurality of transmissive areas.

8. The display device of claim 1, wherein the common electrode includes a first common electrode portion in the normal area and a second common electrode portion in the optical area, and
wherein a thickness of the first common electrode portion is larger than a thickness of the second common electrode portion.

9. The display device of claim 1, wherein a work function value of the transparent electrode is lower than a work function value of the common electrode.

10. The display device of claim 1, wherein a lowest unoccupied molecular orbital value or work function value of the conductive material layer is lower than a work function value of the common electrode and higher than a work function value of the transparent electrode.

11. The display device of claim 1, wherein a thickness of the transparent electrode is larger than a thickness of each of the conductive material layer and the common electrode.

12. The display device of claim 1, further comprising:
an encapsulation layer on the transparent electrode; and
a touch sensor on the encapsulation layer, the touch sensor non-overlapping with the plurality of transmissive areas, the plurality of first emission areas and the plurality of second emission areas.

13. A display device, comprising:
a substrate;
a circuit layer on the substrate;
a pixel electrode on the circuit layer;
a light emitting layer on the pixel electrode;
a common electrode on the light emitting layer;
an encapsulation layer on the common electrode;
a metal layer between the common electrode and the encapsulation layer; and
an organic layer or an inorganic layer between the common electrode and the metal layer.

14. The display device of claim 13, wherein the substrate includes a normal area including a plurality of first emission areas and an optical area including a plurality of second emission areas and a plurality of transmissive areas,
wherein the metal layer is in the optical area, out of the normal area and a transparent electrode.

15. The display device of claim 13, wherein the substrate includes a normal area including a plurality of first emission areas and an optical area including a plurality of second emission areas and a plurality of transmissive areas,
wherein the organic layer or the inorganic layer is in the optical area, out of the normal area and the organic layer or the inorganic layer is conductive.

16. A display device, comprising:
a substrate including a normal area including a plurality of first emission areas and an optical area including a plurality of second emission areas and a plurality of transmissive areas;
a first electrode over the substrate;
a conductive material layer on the first electrode; and
a transparent electrode on the conductive material layer.

17. The display device of claim 16, wherein the conductive material layer and the transparent electrode are in the optical area and not in the normal area.

18. The display device of claim 16, wherein the conductive material layer includes an organic material or an inorganic material that is conductive.

19. The display device of claim 16, wherein a thickness of the first electrode in the normal area is greater than a thickness of the first electrode in the optical area.

20. The display device of claim 16, wherein the first electrode is a common electrode.
